(19) United States
(12) Patent Application Publication
(10) Pub. No.: US 2006/0027833 A1
(43) Pub. Date: Feb. 9, 2006

(54) Silicon carbide semiconductor device and method of manufacturing the same

(75) Inventor: Satoshi Tanimoto, Yokohama-shi (JP)

Correspondence Address: MCDERMOTT WILL & EMERY LLP, 600 13TH STREET, N.W., WASHINGTON, DC, 20005-3096, US

(73) Assignee: NISSAN MOTOR CO., LTD.

(21) Appl. No.: 11/194,700

(22) Filed: Aug. 2, 2005

(30) Foreign Application Priority Data
Aug. 4, 2004 (JP) P2004-227704

(51) Int. Cl. H01L 29/74

(52) U.S. Cl. 257/173

(57) ABSTRACT

A silicon carbide semiconductor device has a silicon carbide substrate, a gate electrode made of polycrystalline silicon, a three-layered gate insulating film made of a silicon oxide film, a silicon nitride film and a silicon nitride thermally-oxidized film, interposed between the silicon carbide substrate and the gate electrode, a polycrystalline silicon thermally-oxidized film provided onto at least a side wall of the gate electrode, and a silicon nitride side-surface thermally-oxidized film provided onto at least a side wall of the silicon nitride film.

### BACKGROUND OF THE INVENTION

The present invention relates to a silicon carbide semiconductor device, which is suitable for high power operation, and a method of manufacturing the silicon carbide semiconductor device.

The silicon carbide (hereinafter abbreviated to SiC) semiconductor can form an pn-junction. The SiC semiconductor has a wider bandgap width than other semiconductors including a silicon (Si) semiconductor and a gallium arsenide (GaAs) semiconductor. A 3C—SiC semiconductor has a bandgap width of 2.23 eV. A 6H—SiC semiconductor has a bandgap width of 2.93 eV. A 4H—SiC semiconductor has a bandgap width of 3.26 eV. As widely known, a trade-off relationship exists between an on-resistance and a reverse breakdown voltage of a power device, which relationship is fundamentally determined by its semiconductor's bandgap width. For this reason, a Si power device can not be expected to achieve a higher performance beyond its physical properties which are determined by a bandgap width of Si. However, if a power device is constituted of SiC with a wide bandgap width, the power device can has a trade-off relationship which is more relaxed than the conventional trade-off relation. This makes it possible to achieve a device which has a remarkably improved on-resistance or reverse breakdown voltage. Otherwise, this makes it possible to achieve a device which has a considerably improved on-resistance and a considerably improved reverse breakdown voltage. In other words, the chip size can be extremely miniaturized while the on-resistance and the reverse breakdown voltage are caused to remain constant.

Among semiconductor devices which have wider bandgap widths, a SiC semiconductor device is the only device, whose silicon oxide (SiO₂) is grown by thermal oxidation as in the case of a Si semiconductor device. For this reason, the SiC semiconductor device is largely expected to be achieved as especially a normally-off MOS drive power device among power devices, for example, a power metal-oxide-semiconductor field effect transistor (MOSFET) or as a power insulated gate bipolar transistor (IGBT).

Nevertheless a pessimistic outlook for reliabilities of a thermally-oxidized film on SiC as follows is prevailing. (1) In an interface between SiO₂ and the semiconductor, theoretically, the thermally-oxidized film shows a smaller electron energy barrier for SiC than for Si. (2) The thermally-oxidized film on SiC includes carbon (C), as impurities which are residues to be produced during oxidation, in considerable amounts. For these reasons, the thermally-oxidized film fundamentally has a higher leakage current on SiC than on Si. Consequently, no matter how the SiC thermally-oxidized film may be improved, the SiC thermally-oxidized film can not achieve reliability (of true cause) equivalent to those of the Si thermally-oxidized film.

In addition, a defect-related dielectric breakdown has been one of the most serious problems these days. Of the Si device, it is widely known that, if crystal imperfection such as dislocation is taken into its thermal oxide film, this causes a dielectric breakdown (although various mechanisms are conceivable) in a lower electric field, and causes a life span against time-dependent dielectric breakdown (TDDB) to be extremely shortened. The present inventor and his group have reported as follows. With regard to the surface of a currently commercially-available SiC substrate, a large amount of dislocation, in the order of 10⁻⁴ locations/cm³, exists even in an epitaxitial substrate. For this reason, in a case where a gate insulating film of power MOSFETs is constituted of a SiC thermally-oxidized film, the life span against the TDDB of the gate oxide film is determined by defects which have been taken into the thermal oxide film. Consequently, the life span with defects becomes shorter, at least by one order of magnitude, than the life span with no defects. (see Tanimoto, S., et al [2004]. Extended Abstracts (The 51^{st} Spring Meeting, 2004); The Japan Society of Applied Physics and Related Societies, p. 434)

The use of a deposited (gate) insulating film would possibly solve the problem with the SiC thermally-oxidized film. However, studies have been just started on gate reliabilities of a metal-insulator-semiconductor (MIS) structure with the deposited insulating film on the SiC substrate, and a very small number of reports on the issue have been so far disseminated. An ONO deposited film has received the best evaluation results from those reports. In this regard, “O” denotes a SiO₂ film, and “N” denotes a Si₃N₄ (silicon nitride; also abbreviated to SiN) film.

Lipkin and his group examine reliabilities of a metal-insulator-semiconductor (MIS) structure having an ONO gate dielectrics, and figure out a maximum insulation strength and a maximum stress electric current strength, as disclosed in Lipkin, L. A., et al [1999]. IEEE trans. Electron Device, vol. 46, p. 5²⁵ (hereinafter referred to as “Non-patent Literature 2”). In the gate electrode, the ONO film is interposed between an n+4H—SiC substrate and a Mo/Au gate electrode. An n⁻ epitaxial layer is grown on the upper surface of the n⁺ 4H—SiC substrate. The ONO film is made of a SiC thermally-oxidized film (bottom), a SiN film and a SiO₂ film (top). The SiN film is formed by use of a low pressure chemical vapor deposition (LPCVD) process. The top film is formed by thermally oxidizing the surface of the SiN film. The maximum dielectric breakdown strength BVox to be figured out is approximately 13.1 MV/cm (value converted to SiO₂). The maximum stress electric current strength BJox to be figured out is approximately 0.25 mA/cm². Incidentally, symbols “+” and “−” affixed to upper right shoulders of symbols representing conduction types n and p of a semiconductor mean high concentration and low concentration, respectively.

On the other hand, Wang and her group evaluates reliabilities of a MIS structure, and figure out BVox=approximately 12.5 MV/cm (value converted to SiO₂) and BJox=approximately 3 mA/cm², as disclosed in Wang, X. W., et al [2000]. IEEE trans. Electron Device, vol. 47, p. 458 (hereinafter referred to as “Non-patent Literature 3”). In the MIS structure, the ONO film is interposed between a 6H—SiC substrate and an Al gate electrode. The ONO film is formed by thermally oxidizing the surface of a Sio₂/SiN film which is laminated by use of a jet vapor deposition (JVD) process.

### SUMMARY OF THE INVENTION

However, the MIS structure using the ONO film (see Non-patent Literatures 2 and 3) have the following problems, and remain to be improved.

A first problem is that the reliabilities of the ONO-filmed MIS structure on SiC has still not been improved to an extent that the reliability of the ONO-filmed MIS structure exceeds that of a MOS structure on Si. For example, the present inventor and his group report examining reliabilities of a MOS structure to be constituted of a thermal oxide film of a 4H—SiC substrate, and report achieving BVox=13.1 MV/cm and BJox>100 mA/cm², as disclosed in Tanimoto, S., et al [2003]. Meter. Sci. Forum, Vol. 433-436, p. 725 (hereinafter referred to as “Non-patent Literature 4). The BVox and the BJox of the MIS structure using the ONO film are at such a low level that they do not exceed those of a MOS structure using a SiC thermal oxide film.

A second problem is that a technique (concerning a structure and a manufacturing method thereof) of forming a low resistance ohmic contact on the substrate (its back side) has not been established. Whether an actual device to which the MIS structure is applied is power MOSFETs or power IGBTs, it is essential that at least one ohmic electrode with a low resistance be arranged on each of the upper surface and the back side of the substrate. However, the related techniques have not give a slightest idea about this pending problem. According to Non-patent Literatures 2 and 3, surprisingly, examinations were made on reliabilities, such as dielectric breakdown, of the the MIS structure, without forming an ohmic electrode on the back side of the substrate. Generally, a method of forming an ohmic electrode with a low resistance on a SiC substrate includes steps of: forming a contact metal made of Ni in a region to which conductive impurities are doped in a high concentration; and annealing the contact metal at a high temperature of 1,000° C. These processes evolving a high temperature heating process and metal contamination needs to be included in the method of manufacturing the MIS structure without deteriorating its reliability (particularly, the N film of the ONO film).

A third problem is that unnecessary parts of the ONO film remain outside a gate region. If unnecessary parts of the ONO film remain outside the gate region, this complicates an ensuing etching process for opening a contact hole. It is desirable that the manufacturing method be configured to include a step of removing the unnecessary parts of the ONO film immediately after the ONO film is formed, in a case where the ONO film is intended to be applied to an actual device such as MOSFETs. A generally-known method which can be easily applied for this purpose includes: forming a structure as disclosed in Non-patent Literature 2; thereafter selectively removing the ONO film in the outer periphery of the gate electrode by use of a photolithography process and a dry etching process; and achieving a structure in which the two ends of the gate electrode are positioned inward of the two ends of the ONO film (a distance between an end of the ONO film and a corresponding end of the gate electrode is used as a margin for exposure matching). In this method, however, a certain margin for photolithography is needed between an end of the ONO film and a corresponding end of the gate electrode, and (in the case of the MOSFETs) between an end of the ONO film and a corresponding end of the contact hole. This is an obstacle to the miniaturization. In addition, a photolithography process is used to selectively remove the unnecessary parts of the ONO film. This makes the manufacturing process longer.

An object of the present invention is to provide a gate structure which solves the first to the third problems with the related techniques, and which is suitable to be miniaturized, and a method of fabricating the gate electrode, which is highly productive, with regard to a silicon carbide semiconductor device and a method of manufacturing the silicon carbide semiconductor device.

In order to solve the aforementioned problems, a semiconductor device according to the present invention has a configuration in which a three-layered gate insulating film made of a silicon oxide film, a silicon nitride film and a silicon nitride thermal-oxidized film is interposed between a silicon carbide substrate and a gate electrode made of polycrystalline silicon, and in which at least a side wall of the gate electrode is provided with a polycrystalline silicon thermally-oxidized film, and at least a side wall of the silicon nitride film is provided with silicon nitride side-surface thermal-oxidized film.

### BRIEF DESCRIPTION OF THE DRAWINGS

FIG. 1 is a sectional view showing a silicon carbide semiconductor device according to the first embodiment of the present invention;

FIG. 2 is a cross sectional view magnifying a part of FIG. 1;

FIG. 3A through FIG. 3I are sectional views showing main procedures of manufacturing the silicon carbide semiconductor device of FIG. 1;

FIG. 4 is a histogram showing dielectric breakdown strengths BEox which respectively represent 50 samples of the ONO-filmed MIS structure thus fabricated;

FIG. 5 shows leakage current density-electric field (J-Eox) characteristics respectively of the conventional MOS structure and the MIS structure according to the first embodiment;

FIG. 6 is a Weibull graph obtained by plotting a distribution of charge-to-breakdown, Q_{BD} per unit area (C/cm²);

FIG. 7 is a sectional view showing a silicon carbide semiconductor device according to the second embodiment of the present invention;

FIG. 8A through FIG. 8F are sectional views showing main procedures of manufacturing the silicon carbide semiconductor device of FIG. 7;

FIG. 9 is a sectional view showing a silicon carbide semiconductor device according to the third embodiment of the present invention; and

FIG. 10A through FIG. 10H are sectional views showing main procedures of manufacturing the silicon carbide semiconductor device of FIG. 9.

### DETAILED DESCRIPTION OF THE PREFERRED EMBODIMENTS

Hereinafter, specific and detailed descriptions will be provided for embodiments of the present invention with reference to the drawings. A SiC substrate on which an epitaxial layer, other layers and an electrode are formed is termed as a substrate unless otherwise described.

In the following descriptions concerning the drawings, if components or parts shown in one figure are the same as, or similar to, those shown in another figure, the same, or similar components or parts are denoted by the same or similar reference numerals and symbols. Descriptive accounts once made will not be repeated, but will be simplified or omitted. It should be noted that the drawings are schematic, and that a relationship between a thickness and a planar dimension, ratio of one layer to another in terms of thickness, and the like do not faithfully represent their realities. Specific thicknesses and dimensions have to be estimated with the following descriptions taken into consideration. It goes without saying that a relationship between a component in one drawing and the same component in another drawing in terms of their dimensions as well as a ratio of a component in one drawing to the same component in another do not faithfully represent their realities.

### First Emdobiment

Structure

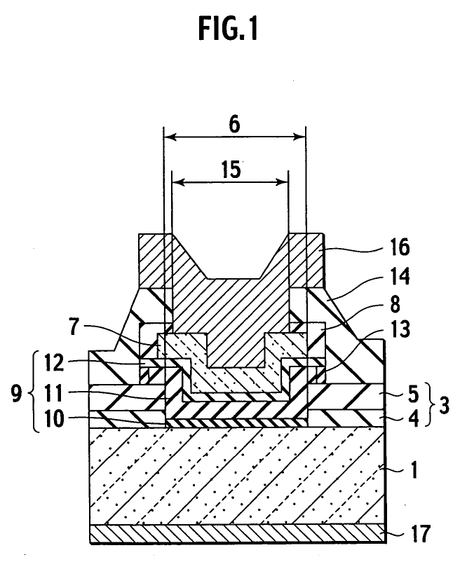

FIG. 1 is a cross-sectional view of a chief part of a silicon carbide semiconductor device (MOS (metal-oxide-semiconductor-structured) capacitor) having a highly-reliable ONO layered-film MIS structure on the basis of the present invention. Reference numeral 1 is an n⁺ 4H—SiC epitaxial substrate, which is obtained by growing an n⁻ exptaxial layer homoepitaxially on the upper surface of a substrate, and which has a high impurity concentration (nitrogen>1×10¹⁹/cm³). Instead of the 4H-substrate, a 6H-substrate, a 3C-substrate, or a 15R-substrate can be used (6H, 3H and 15R mean a hexagonal system, a cubic system and a rhombohedral system respectively). A field insulating film 3 with a thickness of equal to or more than 100 nm is formed on the epitaxial substrate 1. The field insulating film 3 has a structure in which an upper insulating film 5 is laid on a lower insulating film 4. The lower insulating film 4 is thinner than the upper insulating film 5, and is formed by thermally oxidizing a SiC substrate (an epitaxial layer in its exact term). The upper insulating film is formed by use of a process other than the thermal oxidizing process (for example, a low-pressure CVD process). A gate window 6 is opened in the field insulating film 3.

Reference numeral 7 denotes a gate electrode made of polycrystalline Si, which is provided onto the upper insulating film 5 in a way that the gate electrode 7 covers the gate window 6. A polycrystalline Si thermally-oxidized film 8 which has been grown by a thermal oxidation process is formed on at least side surface of the polycrystalline Si gate electrode 7. An ONO gate insulating film 9, which is three-layered, is interposed between the SiC epitaxial substrate 1 on the bottom of the gate window 6 and the gate electrode 7. A lowermost layer (nearest to the substrate) of the three layers is a SiC thermally-oxidized film 10 with a predetermined thickness (for example, 10 nm in thickness), which has been formed by thermally oxidizing the surface of the SiC epitaxial substrate. The SiC thermally-oxidized film 10 is formed locally in the bottom area of the gate window 6. However, in a case where structural restraints stemming from an device, which this structure is applied to, makes it impossible to use the SiC thermally-oxidized film, this film can be replaced with a film which is obtained by thermally treating a SiO₂ film, formed by a low-pressure chemical vapor deposition (LPCVD) proccess, in an oxidation or inert atmosphere at a temperature of 850° C. to 1,000° C.

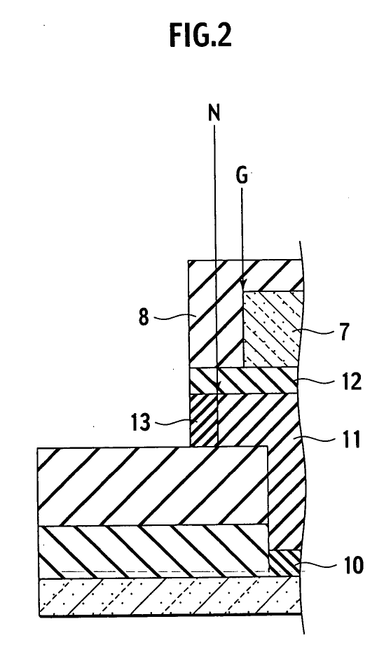

The middle layer and the uppermost layer (constituting an ON part) of the three layers are respectively a SiN film 11, which has been deposited by use of an LPCVD process, and a SiN thermally-oxidized film 12 (i.e., a SiO₂ film), which has been grown by means of thermally oxidizing the SiN film 11. The SiN film 11 and the SiN thermally-oxidized film 12 are formed in a way that they extend on the field insulating film 3, and in a way that they share an outer end with the gate electrode 7 closely (the outer ends respectively of the gate electrode 7, the SiN film 11 and the SiN thermally-oxidized film 12 are located at the same position). An example of thicknesses of the SiN film 11 is 53 nm, and an example of thickness of the SiN thermally-oxidized film 12 is 5 nm. A SiN side-surface thermally-oxidized film 13 (i.e., a SiO₂ film) is arranged on the side surface of the outer portion of the SiN film 11. The SiN side-surface thermally-oxidized film 13 is a thin film, and is grown by means of thermally oxidizing the SiN film 11. FIG. 2 is a diagram showing the end portion of the polycrystalline Si gate electrode 7 in a magnified manner. As understood from FIG. 2, the polycrystalline Si gate electrode 7 is arranged in a way that the outer end G of the polycrystalline Si gate electrode 7 is located inward of the outer end N of the SiN film 11 in the ONO gate insulating film 9. If the positional relationship between the outer ends G and N is not secured, this deteriorates reliabilities (dielectric breakdown strength and the like) of the ONO-filmed MIS structure extremely. Careful attention needs to be paid to the positional relationship.

An interlayer dielectric 14 is formed on the gate electrode 7 and the field insulating film 3. Reference numeral 15 denotes a gate contact window which is opened in the interlayer dielectric 14 in a way that the gate contact window 15 penetrates through the interlayer dielectric 14 to the gate electrode 7. A configuration may be adopted, in which the gate contact window 15 is provided onto the field insulating film 3, instead of the inside of the gate window 6 as shown in FIG. 1. Reference numeral 16 denotes an interconnection for connecting the gate electrode 7 with another circuit component in the same substrate as the gate electrode is located, and with an external circuit, through the gate contact window 15.

An ohmic electrode 17 whose resistance is extremely low is arranged on the back side of the SiC substrate 1. This electrode 17 is formed in the following manner. First, an contact metal such as Ni is deposited on the back side of the substrate 1. Thereafter, the contact metal thus deposited is alloyed with SiC by use of a rapid thermal process at a temperature lower than the thermal oxidation temperature of the SiC thermally-oxidized film 10 in the ONO gate insulating film 9 (for example, at 1,000° C. if the thermal oxidation temperature is 1,100° C.).

Method of Manufacturing

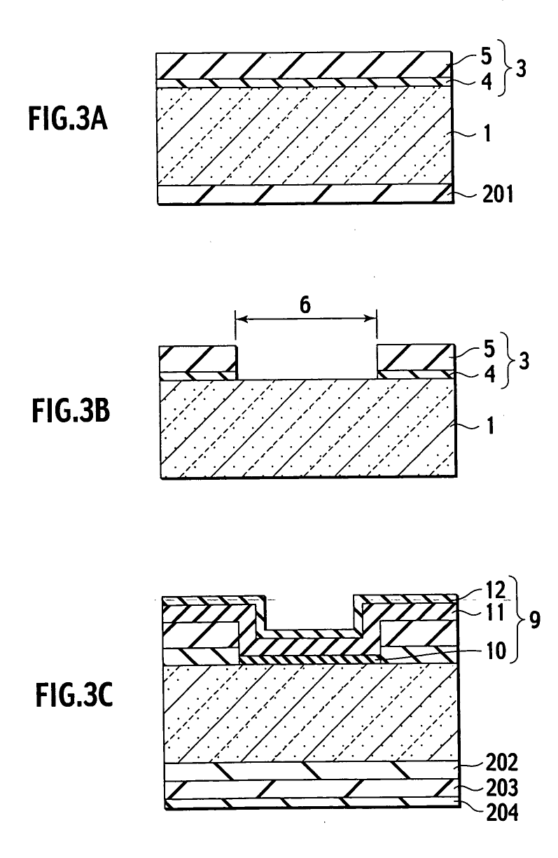

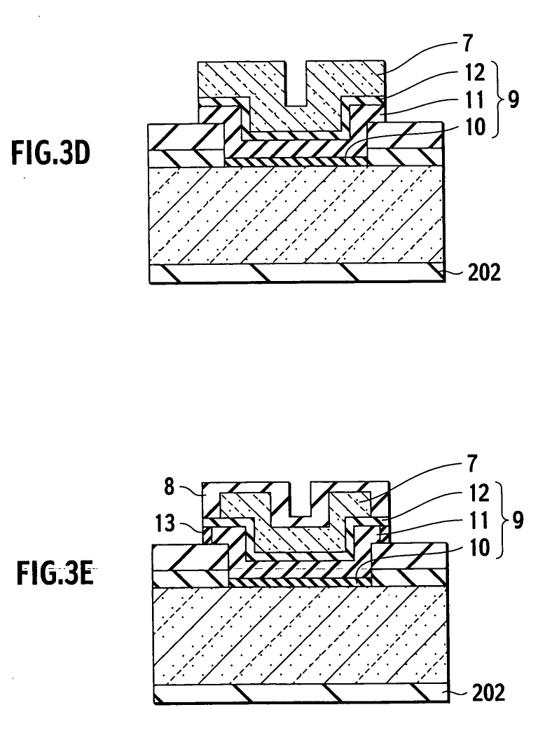

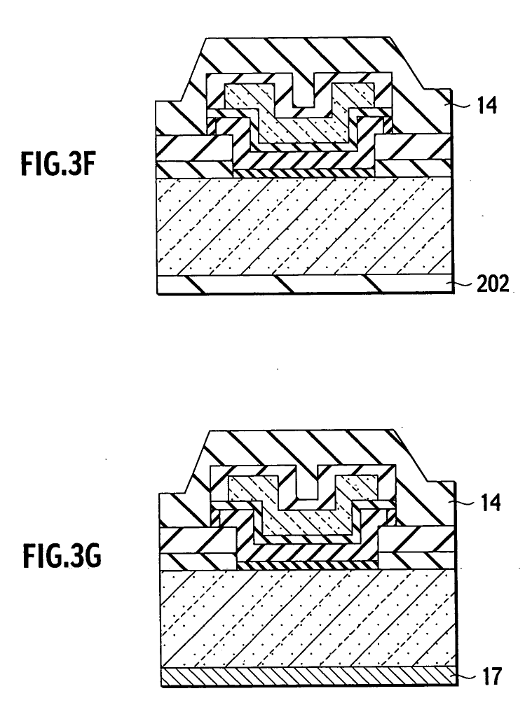

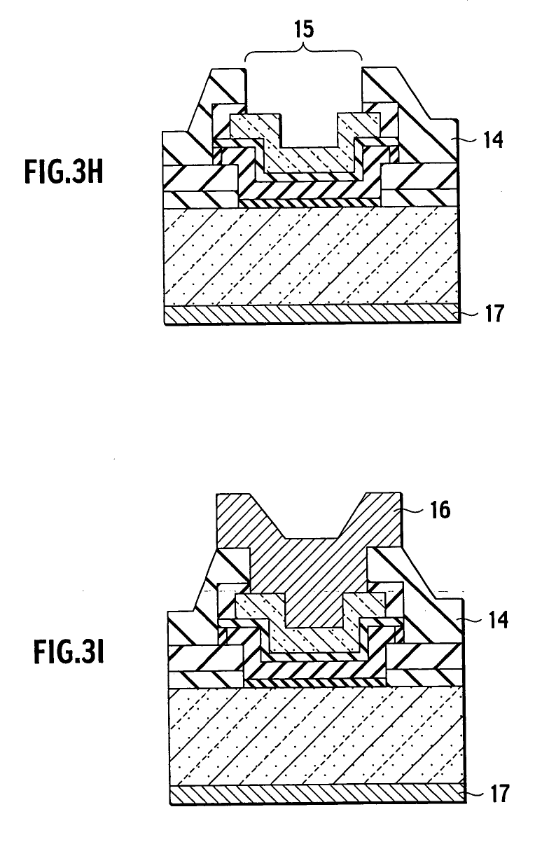

Next, descriptions will be provided for a method of manufacturing the ONO-filmed MIS structure (as shown in FIG. 1) according to the first embodiment of the present invention with reference to FIG. 3A to FIG. 3I.

A. A high-quality n⁻ epitaxial layer is grown on the upper surface of the substrate 1, and thereby the n⁺ 4H—SiC epitaxitial substrate 1 with an 8 degrees off-cut towards the (0001)_{Si} surface is formed. Subsequently, the n⁺ 4H—SiC epitaxitial substrate 1 thus formed is fully cleaned by an RCA cleaning process (a method of cleaning a semiconductor substrate, which is a combination of a cleansing by use of an H₂O₂+NH₄OH mixed solution and a cleaning by use of an H₂O₂+HCl mixed solution) or the like. Thereafter, the n⁺ 4H—SiC epitaxitial substrate 1 is oxidized with the dry oxygen gas. As shown in FIG. 3A, the field insulating film 3 is formed on the upper surface of the substrate 1, and is fabricated of the lower insulating film 4 and the upper insulating film 5, which is thicker than the lower insulating film 4. A thermal SiO₂ film with a thickness of approximately 10 nm can be used for the lower insulating film 4. The SiO₂ film is formed by preparing the surface of the epitaxial substrate 1 by dry oxidation in an oxygen atmosphere. An insulating film with a desired thickness which is formed by a process other than the thermal oxidation process or an equivalent film can be used for the upper insulating film 5. For example, a SiO₂ film with a thickness of 400 nm which is formed by an atmospheric pressure CVD process using oxygen and silane can be used for the upper insulating film. The thermal oxidation of the lower insulating film 4 is not limited to the dry oxidation, but may be a wet oxidation or a thermal oxidation using another oxidizing gas. It is advantageous that the thickness of the lower insulating film 4 be smaller than 50 nm. It is preferable that the thickness of the lower insulating film 4 be 5 nm to 20 nm. The upper insulating film 5 may be formed after the lower insulating film 4 is grown on the surface of the epitaxial substrate 1, as described above. On the contrary, the lower insulating film 4 may be grown between the epitxial substrate 1 and the upper insulating film 5 by thermal oxidation after the upper insulating 5 is formed. Reference numeral 201 in FIG. 3A denotes a first transitory SiC thermally-oxidized film (SiO₂) which is naturally formed on the back side of the substrate 1 when the lower insulating film 4 is formed. The first transitory SiC thermally-oxidized film 201 is not a meaningless film, but has a function of effectively removing a considerably-deep, grinding-induced damaged layer in the back side of the substrate 1.

B. Next, the surface of the SiC substrate 1 is coated with photoresist, and is exposed to light, and is developed. Thereafter, the SiC substrate 1 is dipped into a buffered hydrofluoric solution (a NH₄F+HF mixed solution), and thereby a wet etching is applied to the SiC substrate 1. Through these processes, the gate window 6 is formed in a predetermined position in the field insulating film 3, as shown in FIG. 3B. This wet etching process causes the first transitory SiC thermally-oxidized film 201 to disappear. In a case where a fine gate window 6 is intended to be formed, a dry etching process, such as a reactive ion-etching process, using CF₄ gas plasma can be used. In this case, however, the dry etching process is applied first, but the field insulating film with a thickness of tens of nanometers is left. Thereafter, it is necessary that the wet etching process using the aforementioned buffered hydrofluoric solution be applied instead of the dry etching process. That is because, if the dry etching process causes the gate window 6 to penetrate through the field insulating film 3, this causes plasma-induced damage on the surface of the SiC substrate so that the surface of the SiC substrate is roughed. The roughed surface is a cause of characteristics degradation of the gate insulating film 9 which is formed in the ensuing process. After the etching of the gate window 6 is completed, the photoresist is removed (as shown in FIG. 3B).

C. Then, the SiC epitaxial substrate 1 is cleaned by means of another RCA cleansing process again. In order to remove the chemically oxidized film which has been formed on the surface of the opening portion by means of the RCA cleansing process, the SiC epitaxial substrate 1 is dipped in the buffered hydrofluoric solution for 5 seconds to 10 seconds. Thereafter, the SiC epitaxial substrate 1 is completely cleaned of the buffered hydrofluoric solution by use of ultrapure water, and subsequently is dried.

The SiC epitaxial substrate 1 is thermally oxidized immediately after the SiC epitaxial substrate 1 is dried up. Thereby, a first layer of the ONO gate insulating film 9, i.e., the SiC thermally-oxidized film 10, is grown on the surface of the epitaxial layer in the bottom of the gate window 6. A condition for this thermal oxidation process may be dry oxidation at a temperature, for example, of 1,100° C.

Actually, as explained above, an ONO-filmed MIS structure whose reliabilities are not deteriorated even by the ensuing contact annealing process and other thermal processes to be performed at a high temperature is achieved. In other words, the important point is to set a temperature, at which the SiC thermally-oxidized film 10 is grown, to be higher than a temperature at which any one of the ensuing thermal processes is performed. A reason why 1,100° C. is chosen as a temperature for the thermal oxidation process is that a rapid thermal annealing is performed later at 1,000° C. for the purpose of forming the ohmic electrode on the back side of the substrate 1.

Reference numeral 202 denotes a second transitory SiC thermally-oxidized film to be naturally formed on the back side of substrate 1 while the SiC thermally-oxidized film 10 is being thermally oxidized. Like the aforementioned first transitory SiC thermally-oxidized film 201, the second transitory SiC thermally-oxidized film 202 has an effect of removing the grinding-induced damaged layer. In addition to this, the second transitory SiC thermally-oxidized film 202 has a function of protecting the back side of the substrate 1 from dry-etching damage which would otherwise be caused while the polycrystalline SiC is removed from the back side of the substrate 1, which will be referred to when descriptions are provided for the ensuing process. If the back side of the substrate 1 were not protected by this oxidized film, this would bring about a problem of disturbing crystallinity of the back side of the substrate 1, and resultantly increasing the contact resistance of the back-side electrode.

After the SiC thermally-oxidized film 10 is formed in the bottom of gate window 6, the SiN film 11 (i.e., the second layer in the ONO film) is deposited on the entire upper surface of the epitaxial substrate 1 by means of a LPCVD process using SiH₂Cl₂ and O₂. Immediately after the deposition is completed, the substrate 1 is pyrogenically oxidized at 950° C. Thereby, the SiN thermally-oxidized film 12 (i.e., the third layer in the ONO film) with a predetermined thickness is grown on the surface of the SiN film 11. FIG. 3C shows a cross-sectional structure of the substrate 1 which has been fabricated until this process. What above the back side of the substrate 1 are denoted by reference numerals 203 and 204 respectively show a transitory SiN film and a transitory SiN thermally-oxidized film, both of which are naturally formed during the deposition of the SiN film 11 and the growth of the SiN thermally-oxidized film 12 respectively.

D. Subsequently, a polycrystalline silicon film with a thickness of 300 nm to 400 nm is formed on each of the entire upper surface and the entire back side of the SiC epitaxial substrate 1 by means of a low pressure CVD process using a silane material (at a growth temperature of 600° C. to 700° C.). Thereafter, phosphorus (P) is added to the polycrystalline silicon film by means of a generally-known thermal diffusion method using phosphorus chlorate (POCl₃) and oxygen (at a processing temperature of 900° C. to 950° C.). Thereby, conductivity is given.

Thereafter, the upper surface of the epitaxial substrate 1 is coated with photoresist, and is exposed to light. Thus, a mask is formed. Thereafter, the polycrystalline Si film, the SiN thermally-oxidized film 12 and the SiN film 11 are etched continuously by means of a reactive ion-etching (RIE) process using SF₆. Thereby, the outer end of the polycrystalline Si gate electrode 7 and the outer end of the ON layer in the ONO gate insulating film are roughly defined (preliminarily defined). Thus, unnecessary parts of the ON layer are etched precisely (in a self-aligning manner) with the same resist mask as the polycrystalline Si gate electrode 7 is etched, in a way that the outer end of the ON layer is located at the same position as the outer end of the polycrystalline Si gate electrode 7 is located when viewed from the side. Incidentally, if an etchant gas, such as CHF₃, which provides a higher etching rate and a higher selective etching ratio to SiN is used when the SiN thermally-oxidized film 12 is intended to be etched by means of the RIE process, evenness in the RIE process can be improved.

After the resist to be used during the RIE process is completely removed, the entire upper surface of the SiC substrate 1 is coated again with a resist material (a photoresist suffices) having a thickness of 1 μm or more. While the entire upper surface of the SiC substrate 1 is being protected in this manner, the SiC substrate 1 is etched by means of a dry etching process. Thus, the polycrystalline Si film, the transitory SiN thermally-oxidized film 204 and the transitory SiN film 203, which are deposited on the back side of the SiC substrate 1 is removed sequentially, and then the resist material to be used for protecting the upper surface of the SiC substrate 1 is removed. Thereafter, a cross-sectional structure as shown in FIG. 3D is obtained.

E. Subsequently, the SiC epitaxial substrate 1 is cleaned again by use of the RCA cleaning process, and then is dried. Thereafter, the SiC epitaxial substrate 1 is oxidized by means of a wet oxidation process (is pyrogenically oxidized) at 950° C. As shown in FIG. 3E, thereby, the polycrystalline Si thermally-oxidized film 8 is formed on the side surface and the upper portion of the polycrystalline Si gate electrode 7, and the SiN side-surface thermally-oxidized film 13 is formed on the side surface of the SiN film 11, at the same time. In this respect, there are three extremely important points for improving the reliabilities of the ONO-filmed MIS structure. A first point is that the leaky outer end of the SiN film which has been damaged during the gate etching is removed by turning the outer end into the SiN side-surface thermally-oxidized film 13. A second point is that the outer end G of the polycrystalline Si gate electrode is located slightly inward of the outer end N of the SiN film, and that accordingly the gate electric field of the outer end of the SiN film is relaxed. In order to cause the outer end G of the polycrystalline Si gate electrode to be located slightly inward of the outer end N of the SiN film, a property that the oxidation rate of the polycrystalline Si gate electrode is higher than that of the SiN film. A third point is that addition of the polycrystalline Si thermally-oxidized film 8 and the SiN side-surface thermally-oxidized film 13 helps to establish an structure in which the ONO gate insulating film 9 is completely sealed with the thermally stable materials, i.e. the polycrystalline Si film, the SiC film and the thermally-oxidized film. This structural establishment plays an important role in preventing the ONO gate insulating film 9 from deteriorating in the course of the ensuing high-temperature contact annealing process (at 1,000° C. and for 2 minutes).

F. After the polycrystalline Si thermally-oxidized film 8 and the SiN side-surface thermally-oxidized film 13 are formed, the interlayer dielectric 14 is deposited on the entire upper surface of the epitaxial substrate 1 (as shown in FIG. 3F). A SiO₂ film with a thickness of approximately 1 μm, which is deposited by means of an atmospheric pressure CVD process using silane and oxygen as materials, phosphorus silicate glass (PSG) with a thickness of approximately 1 μm, which is obtained by further adding phosphorus (P) to the SiO₂ film, and the like are suitable for materials for the interlayer dielectric. However, materials for the interlayer dielectric are not limited to the SiO₂ film or phosphorus silicate glass. Any other material may be used as long as the material can go through various heating process to follow this process. Thereafter, the substrate 1 is put into a generally-used diffusion furnace, and is mildly thermally processed in a N₂ atmosphere for tens of minutes. Thus, the interlayer dielectric 14 is highly densified. A temperature for this thermal process is chosen to be lower than 1,100° C. which is used during the SiC thermal oxidation process, for example, to be in a range of 900° C. to 1,000° C., depending on the necessity.

G. Subsequently, the upper surface of the epintaxial substrate 1 is coated with photoresist. Then, a post bake is applied thereto sufficiently, and thus volatile components of the resist are completely vaporized. Thereafter, the epitaxial substrate 1 is dipped into the buffered hydrofluoric solution, and thus the second transitory SiC thermally-oxidized film 202 which has remained on the back side of the substrate 1 is completely removed. Then, the substrate is cleaned of the buffered hydrofluoric solution by use of ultrapure water. The C terminated surface of the back side of the SiC substrate 1 thus exposed is a clean surface free of damage or contamination.

The epitaxial substrate 1, which is wet with the utrapure water, is dried. Immediately after the drying, the epitaxial substrate 1 is installed into an evaporation system which is kept in high vacuum. Thus, an ohmic-contact base material, which is desired, is deposited on the back side of the substrate 1. For example, a Ni film with a thickness of 50 to 100 nm can be used as the ohmic-contact base material.

After the evaporated ohmic-contact base material is deposited, the resist on the upper surface of the substrate 1 is completely removed with a specialized stripper solution, and the substrate 1 is cleaned fully. Thereafter, the substrate 1 is dried. Immediately after the drying, the substrate 1 is installed into a rapid thermal annealing system. Thus, a contact annealing process is applied to the substrate 1 in a 100% pure Ar atmosphere at 1,000° C. for two minutes. Through this heating treatment, the Ni film is alloyed with the low-resistance SiC substrate (is made into silicide), as shown in FIG. 3G. As a result, the ohmic electrode 17 with an extremely low resistance, which has a contact resistance in the order of at least 10⁻⁶ Ωcm², is obtained.

H. The upper surface of the substrate 1 is coated with photoresist, and then is exposed and developed by use of an exposure system. Thus, a resist mask through which the gate contact window 15 is opened in the interlayer dielectric is formed. Thereafter, the entire back side of the substrate 1 is coated with photoresist as a protecting film, and then is dried fully. Subsequently, an etching process is performed by use of the buffered hydrofluoric solution so that the gate contact window 15 is opened in the interlayer dielectric 14 and the polycrystalline Si thermally-oxidized film 8 (the upper surface portion thereof). The photoresist on the back side of the substrate 1 plays a role of preventing the ohmically-contacted electrode 17 from disappearing or deteriorating as a result of the ohmically-contacted electrode 17 being liquated out into the buffered hydrofluoric solution. In addition, the photoresist on the back side of the substrate 1 plays a role of preventing the upper surface of the epitaxial substrate 1 from being contaminated by the ohmic contact material which would otherwise be liquated from the back side of the substrate 1. After the photoresist is completely removed by a specialized stripper solution, a structure as shown in FIG. 3H is obtained.

I. Subsequently, the substrate 1 is cleaned fully. After being cleaned, the substrate 1 is dried. Then, the substrate 1 is quickly installed into a magnetron sputtering system which is kept in high vacuum. Thus, a desired wiring material, for example, Al with a thickness of 1 μm is deposited on the entire upper surface of the epitaxial substrate 1.

Thereafter, the upper surface of the substrate 1 on which the Al film is formed is coated with photoresist, and the photoresist is exposed and developed. After a resist mask is formed in this manner, the back side of the substrate 1 is again coated with photoresist for protecting the back-side electrode. After the resist is dried fully, the Al film is patterned by use of a phosphoric-acid-containing etching solution. Accordingly, the interconnection 16 is formed. The resist on the back side of the substrate 1 is formed for the purpose of preventing the ohmic electrode 17 from disappearing or degenerating as a result of the ohmic electrode 17 being liquated out into the phosphoric-acid-containing etching solution. However, in a case where it is unlikely that the back-side electrode may not disappear or degenerate, or in a case where the Al film is etched by means of an RIE process, the resist on the back side of the substrate 1 can be omitted. Finally, the resist mask and the resist to be used for protecting the back-side electrode are completely removed by use of a specialized stripper solution. After the substrate is cleaned fully, the substrate is dried. Thus, a final structure as shown in FIG. 31 is obtained. In this manner, the silicon carbide semiconductor device with the ONO-filmed MIS structure according to the first embodiment of the present invention is completed.

As described above, the silicon carbide semiconductor device according to the first embodiment of the present invention has the configuration in which the three-layered gate insulating film 9 made of the silicon oxide film 10, the silicon nitride film 11 and the silicon nitride thermally-oxidized film 12 is interposed between the silicon carbide substrate 1 and the gate electrode 7 made of polycrystalline silicon, and in which at least the side wall of the gate electrode 7 is provided with the polycrystalline silicon thermally-oxidized film 8, and at least the side wall of the silicon nitride film 11 is provided with the silicon nitride side-surface thermal-oxidized film 13.

In addition, the outer end of the polycrystalline silicon thermally-oxidized film 8 is located at the same position as the outer end of the silicon nitride side-surface thermally-oxidized film 13 is located, when viewed from the side. The outer end of the silicon nitride film 11 is positioned outward of the outer end of the gate electrode 7.

Furthermore, the three-layered gate insulating film 9 made of the silicon oxide film 10, the silicon nitride film 11 and the silicon nitride thermally-oxidized film 12 is interposed between the silicon carbide substrate 1 and the gate electrode 7 made of polycrystalline silicon. The side wall of the gate electrode 7 is provided with the polycrystalline silicon thermally-oxidized film 8, and the side wall of the silicon nitride film 11 is provided with the silicon nitride side-surface thermal-oxidized film 13. The silicon nitride thermally-oxidized film 11 and the gate electrode 7 are provided thereto in a way that the outer end of the silicon nitride film 11 is positioned outward of the outer end of the gate electrode 7.

Moreover, the interlayer dielectric 14 is provided onto the upper surface of the silicon carbide semiconductor device in a way that at least a part of the upper portion of the gate electrode 7 is covered by the interlayer dielectric 14. The ohmic electrode 17 to be contacted with the silicon carbide substrate 1 is provided into the predetermined position on the back side or the upper surface of the silicon carbide semiconductor device.

Additionally, the three-layered gate insulating film 9 is made of the silicon oxide film 10, the silicon nitride film 11 and the silicon nitride thermally-oxidized film 12, and is provided in a way that the three-layered gate insulating film 9 covers the bottom of the gate window 6. The three-layered gate insulating film 9 is interposed between the gate electrode 7 made of polycrystalline silicon and the silicon carbide substrate 1, on whose upper surface the field insulating film 3 is formed. The gate window 6 is opened in the field insulating film 3. The side wall of the gate electrode 7 is provided with the polycrystalline silicon thermally-oxidized film 8, and the side wall of the silicon nitride film 11 is provided with the silicon nitride side-surface thermal-oxidized film 13. The silicon nitride thermally-oxidized film 11 and the gate electrode 7 are provided thereto in a way that the outer end of the silicon nitride film 11 is positioned outward of the outer end of the gate electrode 7.

In the case of the method of manufacturing a silicon carbide semiconductor device according to the first embodiment of the present invention, the silicon oxide film 10 is formed by thermally oxidizing the silicon carbide substrate 1. Incidentally, the silicon oxide film 10 may be formed by depositing the silicon oxide film by means of a chemical vapor deposition process, and by thereafter thermally treating the silicon oxide film thus deposited in an oxygen atmosphere or in an inactive atmosphere.

In addition, the method of manufacturing a silicon carbide semiconductor device according to the first embodiment of the present invention includes a step of forming the polycrystalline silicon thermally-oxidized film 8 and the silicon nitride side-surface thermally-oxidized film 13 by means of a thermal oxidation process at the same time.

Furthermore, the method of manufacturing a silicon carbide semiconductor device according to the first embodiment of the present invention includes a step of continuously etching the gate electrode 7 and the silicon nitride film 11 by use of the same mask so that the outer ends respectively of the gate electrode 7 and the silicon nitride film 11 are preliminarily defined, and a step of thermally oxidizing the gate electrode 7 and the silicon nitride film 11 at the same time so that the outer ends respectively of the gate electrode 7 and the silicon nitride film 11 are finally determined.

Moreover, the step of continuously etching the gate electrode 7 and the silicon nitride film 11 by use of the same mask is a step in which the continuous etching process is stopped without the continuous etching process does not penetrate the silicon oxide film 10.

The method of manufacturing a silicon carbide semiconductor device according to the first embodiment of the present invention includes steps of: sequentially laying the silicon oxide film 10, the silicon nitride film 11 and the silicon nitride thermally-oxidized film 12 over one anther on the silicon carbide substrate 1, and thus forming the three-layered gate insulating film 9; laying the gate electrode 7, which is made of polycrystalline silicon, over the silicon nitride thermally-oxidized film 12; continuously removing an unnecessary part of the gate electrode 7 and an unnecessary part of the silicon nitride film 11 from the silicon carbide substrate 1 by use of the same mask, and thus preliminarily defining the outer ends respectively of the gate electrode 7 and the silicon nitride film 11; and thermally oxidizing the gate electrode 7 and the silicon nitride 11, thus forming the polycrystalline silicon thermally-oxidized film 8 on the side wall of the gate electrode 7 and the silicon nitride side-surface thermally-oxidized film 13 on the side wall of the silicon nitride film 11, thereafter positioning the outer end of the gate electrode 7 inward of the outer end of the silicon nitride film 11.

Additionally, the method of manufacturing a silicon carbide semiconductor device according to the first embodiment of the present invention includes steps of: forming on the silicon carbide substrate 1 the field insulating film 3 in which the gate window 6 is opened; sequentially laying the silicon oxide film 10, the silicon nitride film 11 and the silicon nitride thermally-oxidized film 12 over one another in a way that the films cover the bottom of the gate window 6, thus forming the three-layered gate insulating film 9; forming the gate electrode 7, which is made of polycrystalline silicon, on the silicon nitride thermally-oxidized film 12; continuously removing the unnecessary part of the gate electrode 7 and the unnecessary part of the silicon nitride film 11 from the silicon carbide substrate 1 by use of the same mask, and thus preliminarily defining the outer ends respectively of the gate electrode 7 and the silicon nitride film 11; and thermally oxidizing the gate electrode 7 and the silicon nitride 11, thus forming the polycrystalline silicon thermally-oxidized film 8 on the side wall of the gate electrode 7 and the silicon nitride side-surface thermally-oxidized film 13 on the side wall of the silicon nitride film 11, thereafter positioning the outer end of the gate electrode 7 inward of the outer end of the silicon nitride film 11.

The method of manufacturing a silicon carbide semiconductor device according to the first embodiment of the present invention includes steps of: sequentially laying the silicon oxide film 10, the silicon nitride film 11 and the silicon nitride thermally-oxidized film 12 over one anther on the silicon carbide substrate 1, and thus forming the three-layered gate insulating film 9; forming the gate electrode 7, which is made of polycrystalline silicon, over the silicon nitride thermally-oxidized film 12; continuously removing an unnecessary part of the gate electrode 7 and an unnecessary part of the silicon nitride film 11 from the silicon carbide substrate 1 by use of the same mask, and thus preliminarily defining the outer ends respectively of the gate electrode 7 and the silicon nitride film 11; thermally oxidizing the gate electrode 7 and the silicon nitride 11, thus forming the polycrystalline silicon thermally-oxidized film 8 on the side wall of the gate electrode 7 and the silicon nitride side-surface thermally-oxidized film 13 on the side wall of the silicon nitride film 11, thereafter positioning the outer end of the gate electrode 7 inward of the outer end of the silicon nitride film 11; depositing the interlayer dielectric 14 in a way that the interlayer dielectric 14 covers the polycrystalline silicon thermally-oxidized film 8; exposing the predetermined area in the silicon carbide substrate 1; providing the ohmic-contact base material into at least the exposed area in the silicon carbide substrate 1; and thermally treating the silicon carbide substrate 1, thereby making the ohmic-contact base material into the low-resistance ohmically-contacted electrode 17.

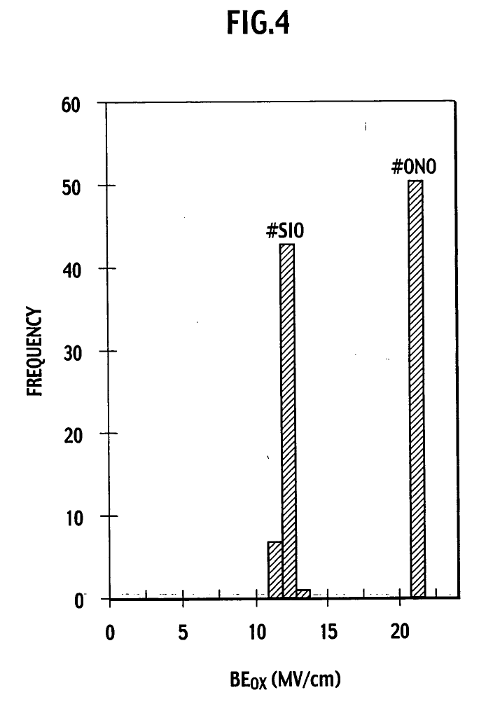

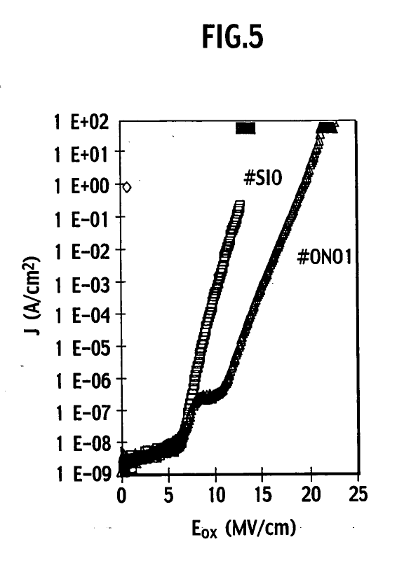

FIG. 4 is a histogram (#ONO) showing dielectric breakdown strengths BEox (MV/cm) which respectively represent 50 samples of the ONO-filmed MIS structure thus fabricated. Resultant insulation strengths (#SIO) of a MOS structure, whose gate insulating film is constituted of only a SiC thermally-oxidized film, and which the present inventor and his group has reported in Non-patent Literature 4, is shown at the same time for a comparison purpose. The area (opening portion) of the gate window was 3.14×10⁻⁴ cm². The converted film thicknesses respectively of the SiO₂ films of the ONO gate insulating film and the comparative gate thermally oxidized film were 42 nm.

An average value of the BEox's of the MOS structure (#SIO) was equal to, or larger than, 12 MV/cm, and the BEox's of the MOS structure (#SIO) exhibited a steep distribution. The maximum value of the BEox's of the MOS structure (#SIO) was 13.1 MV/cm. These BEox's were equal to, or better than, those of the ONO-filmed MIS structure, which were reported in Non-patent Literatures 2 and 3. By contrast, the BEox distribution (#ONO) of the ONO-filmed MIS structure according to the first embodiment of the present invention had an average value of 21 MV/cm, which was a surprisingly high value; Through this, it is understood that the ONO-filmed MIS structure according to the first embodiment of the present invention achieved an remarkable improvement in the insulation strength in comparison with the conventional MOS structure and the conventional ONO-filmed MIS structure. Furthermore, variation in dielectric breakdown strength among the samples of the ONO-filmed MIS structure according to the first embodiment of the present invention was decreased so that the variation was equal to, or less than half of those of the conventional MOS structure (#SIO).

FIG. 5 shows leakage current density-electric field (J-Eox) characteristics respectively of the conventional MOS structure and the MIS structure according to this embodiment. It was understood that leakage current in the MIS structure according to the first embodiment of the present invention was decreased by four orders of magnitude in an electric field area with an electric field Eox equal to, or stronger than, 7.5 MV/cm, in comparison to leakage current in the conventional MOS structure. In addition, the maximum stress current density (i.e., current density to appear immediately before dielectric breakdown) of the ONO-filmed MIS structure according to the first embodiment of the present invention, which was extracted from FIG. 5, was 40 A/cm². This value was larger, by equal to or more than two digits, than that of the conventional MOS structure (#SIO) to be used for the comparison purpose. In addition, this value was superior, by equal to or more than four orders, to those respectively of the ONO-filmed MIS structural bodies which have been described in Non-patent Literatures 2 and 3.

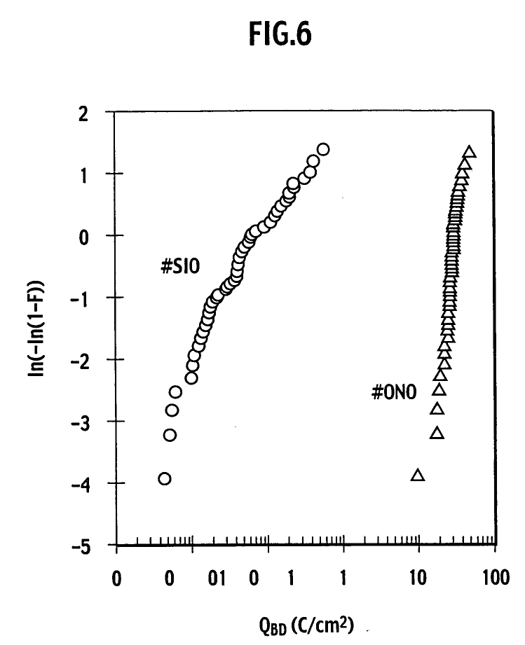

FIG. 6 is a Weibull graph which is obtained by plotting a distribution of charge density Q_{BD} per unit area (C/cm²) which passed through the gate insulating film until a time-dependent dielectric breakdown (TDDB) occurred in each of the conventional MOS structure and the ONO-filmed MIS structure according to the first embodiment of the present invention when a low current stress was applied to each of the two structures, thus showing the distribution. The number of samples to be used for this experiment was approximately 50. Q_{BD} is an important index for measuring the reliability relative to the life span. The Q_{BD}'S of the ONO-filmed MIS structure according to the first embodiment of the present invention were higher, by double to triple orders of magnitude, than those of the conventional MOS structure. Through this, it was understood that the TDDB durability (life span) of the ONO-filmed MIS structure according to the first embodiment of the present invention was improved to a large extent. All of the Q_{BD}'S were higher than 10 C/cm². These values were preferable ones, which were comparable to the Q_{BD}'S of the thermally-oxidized-film MOS structure with a film thickness equal to that of the ONO-filmed MIS structure according to the first embodiment of the present invention, the thermally-oxidized-film MOS structure being formed on the Si substrate. The Q_{BD}'S of the conventional MOS structure were distributed in a range of double to triple orders of magnitude. By contrast, the Q_{BD}'S of the ONO-filmed MIS structure according to the first embodiment of the present invention were distributed narrowly in a range of approximately single to double orders of magnitude. This narrower distribution in addition to the improved life span means that the application of the ONO-filmed structure according to the first embodiment of the present invention virtually solved the degraded lifespan and the variation in lifespan stemming from the imperfection of the SiC substrate which was apparent in the thermally-oxidized-film MOS structure.

As clearly understood from the result of the aforementioned reliability test, the silicon carbide semiconductor device including the ONO-filmed MIS structure according to the present invention and the method of manufacturing the silicon carbide semiconductor device according to the present invention have an effect of completely solving the problem of having been unable to improve the reliability of the conventional ONO-filmed MIS structure to an extent that the reliability of the conventional ONO-filmed MIS structure exceeds that of the conventional SiC thermally-oxidized-film MOS structure, which problem the conventional ONO-filmed MIS structure has suffered, and an effect of achieving an extremely high durability against the dielectric breakdown and an extremely high durability against the TDDB.

In addition, as clearly understood from the foregoing descriptions, in the case of the silicon carbide semiconductor device and the manufacturing method thereof according to the first embodiment of the present invention, at least the ohmic contact with the extremely low resistance in the order of 10⁻⁶ Ωcm² is realized in the back side of the substrate 1 without decreasing the reliability and the yield of the ONO gate insulating film. In other words, the silicon carbide semiconductor device and the manufacturing method thereof according to the first embodiment of the present invention have an effect of solving the problem of having still not established techniques (with regard to the structure and the manufacturing method) for forming the ohmic contact with the low resistance on the SiC substrate, which problem the conventional ONO-filmed MIS structure has suffered.

Furthermore, as clearly understood from the foregoing descriptions, in the case of the silicon carbide semiconductor device and the manufacturing method thereof according to the first embodiment of the present invention, a technique is provided, which causes the unnecessary part of the SiN insulating film in the periphery of the ONO gate insulating film to be self-aligned with the outer end of the gate electrode, and which thus removes the unnecessary part from the upper surface of the substrate 1 neither too much nor too little, without decreasing the reliability and the yield of the ONO gate insulating film. In other words, the silicon carbide semiconductor device and the manufacturing method thereof according to the first embodiment of the present invention have an effect of solving the problem of leaving the unnecessary part of the ONO film outside the gate area, which problem the conventional techniques has been faced with. Additionally, it can be said that the manufacturing method thereof according to the first embodiment includes a step shorter than that of the method of removing the unnecessary part of the SiN film, which method is realized by the simple combination of the standard photolithography technique and the standard dry etching technique. It can be also said that the silicon carbide semiconductor device according to the present invention includes a structure which is suitable for reducing the size of the device.

### Second Embodiment

The example of the configuration of the MIS structure with the ONO gate insulating film in which the field insulating film 3 is arranged on the substrate 1 on each of the two flanks of the gate area has been given to the first embodiment. However, the present invention is not limited to the MIS structure with such a field insulating film 3. As described below, the present invention can be applied to a structure without such a field insulating film 3. According to the present invention, the structure without such a field insulating film 3 obtains the same effects as the MIS structure with such a field insulating film 3 does.

Structure

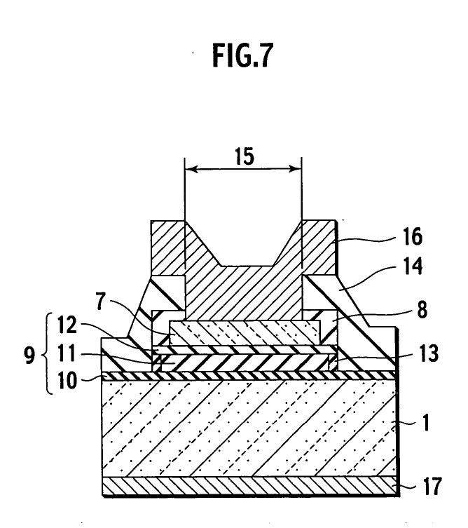

FIG. 7 is a cross-sectional view of a chief part of a silicon carbide semiconductor device including a highly-reliable ONO layered-film MIS structure according to a second embodiment of the present invention. Components, which are denoted by the same reference numerals as the components in the first embodiment are denoted, are the same as those in the first embodiment. For this reason, descriptions will be simplified, or be omitted according to cases, in order to avoid redundancy.

Reference numeral 1 is an n+SiC epitaxial substrate including an n⁻ epitaxial layer on the upper surface of the substrate. Reference numeral 7 is a gate electrode made of polycrystalline Si. A polycrystalline Si thermally-oxidized film 8 to be grown by means of a thermal oxidation process is formed on at least a side surface. What is interposed between the epitaxial substrate 1 and the gate electrode 7 is a three-layered ONO gate insulating film 9. The lowermost layer (nearest to the substrate 1) in this three-layered structure is a SiC thermally-oxidized film 10 with a predetermined thickness (for example, a thickness of 10 nm) which is formed by thermally oxidizing the upper surface of the epitaxial substrate 1. The middle layer and the uppermost layer (nearest to the gate electrode 7) of the three-layered structure are respectively a SiN film 11, which is deposited by use of an LPCVD process, and a SiN thermally-oxidized film 12, which is grown by means of oxidizing the surface of the SiN film 11. The SiN film 11 and the SiN thermally-oxidized film 12 are formed in a way that they share an outer end with the gate electrode 7 closely (the outer ends respectively of the gate electrode 7, the SiN film 11 and the SiN thermally-oxidized film 12 are located at the same position). An example of thickness of the SiN film 11 is 53 nm, and an example of thickness of the SiN thermally-oxidized film 12 is 5 nm. A SiN side-surface thermally-oxidized film 13 is arranged on the side surface of the outer portion of the SiN film 11. The SiN side-surface thermally-oxidized film 13 is a thin film, and is grown by means of thermally oxidizing the SiN film 11. In the second embodiment, the polycrystalline Si gate electrode 7 has to be arranged in a way that the outer end G of the polycrystalline Si gate electrode 7 is located inward of the outer end N of the SiN film 11, as shown in FIG. 2. In a case where the outer end G is located outward of the outer end N, or in a case where the outer end G is located at the same position as the outer end N is located, the reliabilities of the ONO-filmed MIS structure thus obtained are decreased drastically. Careful attention needs to be paid to the controlling of positional relationship between the outer ends.

An interlayer dielectric 14 is formed above the gate electrode 7 and the SiC thermally-oxidized film 10 around the gate electrode 7. A gate contact window 15 is opened in the interlayer dielectric 14 in a way that the gate contact window 15 penetrates through the interlayer dielectric 14 to the gate electrode 7. Reference numeral 16 denotes an interconnection for connecting the gate electrode 7 with another circuit component in the same substrate as the gate electrode is located, and with an external circuit, through the gate contact window 15.

An ohmic electrode 17 whose resistance is extremely low is arranged on the back side of the SiC substrate 1. This ohmic electrode 17 is formed in the following manner. First, an evaporated contact metal such as Ni is deposited on the back side of the substrate 1. Thereafter, the contact metal thus deposited is alloyed with SiC by use of a rapid heating treatment at a temperature lower than the thermal oxidation temperature of the SiC thermally-oxidized film 10 in the ONO gate insulating film 9 (for example, at 1,000° C. if the thermal oxidation temperature is 1,100° C.).

Manufacturing Method

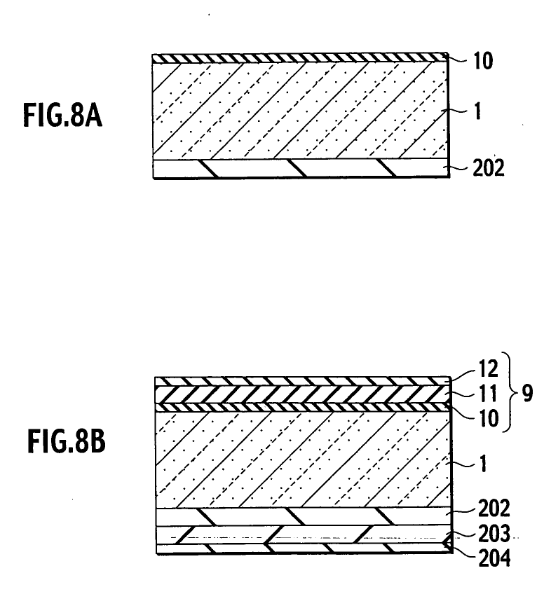

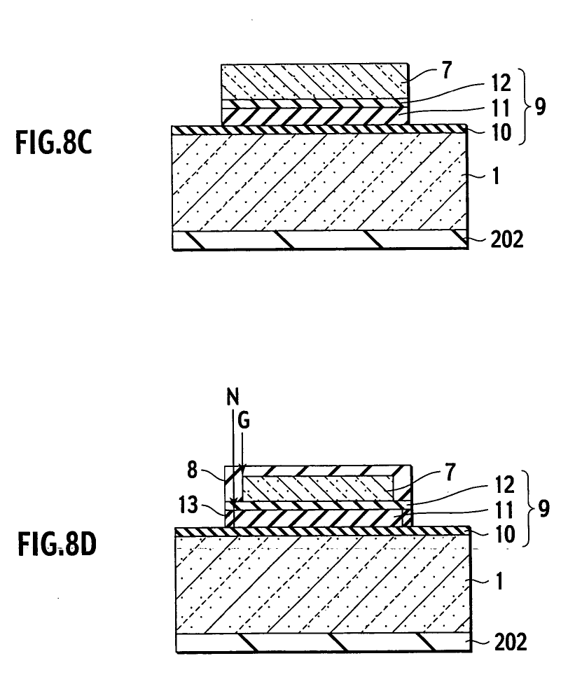

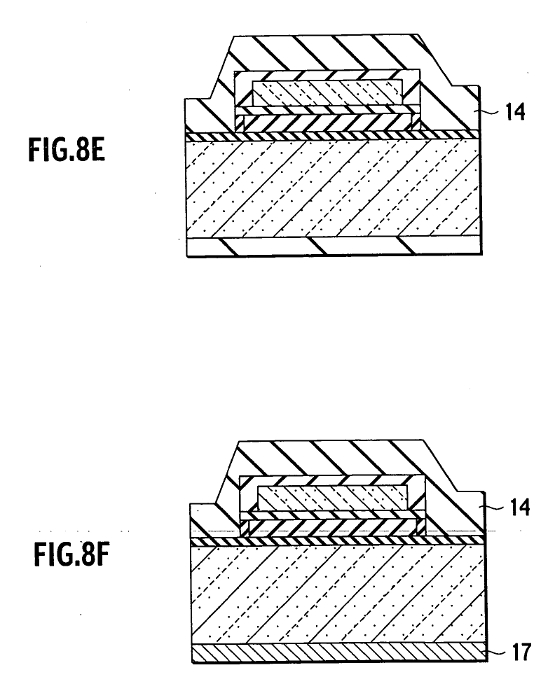

Next, descriptions will be provided for a method of manufacturing the ONO-filmed MIS structure (as shown in FIG. 7) according to the second embodiment of the present invention with reference to FIGS. 8A to 8F.

A. A high-quality n⁻ epitaxial layer is grown on the upper surface of the substrate 1, and thereby the n⁺ 4H—SiC epitaxitial substrate 1 with an 8 degrees off-cut towards the (0001)_{Si} surface is formed. Subsequently, the n⁺ 4H—SiC epitaxitial substrate 1 thus formed is fully cleansed by an RCA cleaning process or the like. Thereafter, the epitaxitial substrate 1 is prepared by dry oxidation, and thereby a SiC thermally-oxidized film (SiO₂) with a thickness of approximately 10 nm is grown on the substrate 1. Immediately after the growth of the SiC thermally-oxidized film, the SiC substrate 1 is dipped into a buffered hydrofluoric solution (a NH₄F+HF mixed solution), and thereby the SiC thermally-oxidized film is removed. Through this sacrificial oxidation process, contamination and crystalline imperfection of the surface of the substrate 1 can be prevented from being taken into the SiC thermally-oxidized film 10 to some extent.

The epitaxial substrate 1 thus sacrificially oxidized is again cleaned by an RCA cleaning process. For the purpose of removing a chemically-oxidized film to be formed on the surface of the epitaxial substrate 1 at the final step of the cleaning process, the epitaxial substrate 1 is dipped in a buffered hydrofluoric solution for 5 to 10 seconds. Thereafter, the epitaxial substrate 1 is completely cleaned of the buffered hydrofluoric solution by use of ultrapure water, and the epitaxial substrate 1 is dried.

Immediately after the drying process, the epitaxial substrate 1 is thermally oxidized, and thereby a SiC thermally-oxidized film 10 of an ONO gate insulating film 9 is grown on the entire upper surface of the epitaxial substrate 1 as shown in FIG. 8A. For example, a dry oxidation process at a temperature of 1,100° C. can be listed as conditions for this oxidation process. However, any other oxidation method and any other oxidation temperature may be used. It is essential that the oxidation temperature be set to be higher than any other thermal treatment temperature to be used in all of the ensuing processes.

Reference numeral 202 denotes a transitory SiC thermally-oxidized film to be naturally formed on the back side of the substrate 1 while the SiC thermally-oxidized film 10 is being thermally oxidized. The transitory SiC thermally-oxidized film 202 has an effect of removing a grinding-attributed induced damaged layer from the back side of the epitaxial substrate 1. In addition to this, the transitory SiC thermally-oxidized film 202 has an important function of protecting the back side of the substrate 1 from dry-etching damage which would otherwise be caused while the polycrystalline SiC is removed from the back side of the substrate 1, which will be referred to when descriptions are provided for the ensuing processes.

B. After the SiC thermally-oxidized film 10 is formed, then, the SiN film 11 (i.e., a second layer of the ONO film) is deposited on the entire upper surface of the epitaxial substrate 1 by means of an LPCVD process using SiH₂Cl₂ and O₂. Immediately after the deposition is completed, the epitaxial substrate 1 is pyrogenically oxidized at 950° C., and thereby a SiN thermally-oxidized film 12 (i.e., a third film of the ONO film) with a predetermined thickness is grown on the upper surface of the SiN film 11. FIG. 8B shows a cross-sectional structure of the substrate 1 which has been fabricated until this step of the processes. What above the back side of the substrate 1 are denoted by reference numerals 203 and 204 respectively are a transitory SiN film and a transitory SiN thermally-oxidized film, both of which are naturally formed during the deposition of the SiN film 11 and the growth of the SiN thermally-oxidized film 12.

C. Next, a polycrystalline silicon film with a thickness of 300 nm to 400 nm is formed on the entire upper surface and the entire back side of the SiC epitaxial substrate 1 by means of a low pressure CVD process using a silane material at a growth temperature of 600° C. to 700° C. Thereafter, phosphorus (P) is doped to the polycrystalline silicon film by means of a generally-known thermal diffusion method using phosphorus chlorate (POCl₃) and oxygen (at a processing temperature of 900° C. to 950° C.). Thereby, conductivity is given.

Thereafter, the upper surface of the epitaxial substrate 1 is coated with photoresist, and is exposed to light. Thus, an etching mask is formed. Thereafter, the polycrystalline Si film, the SiN thermally-oxidized film 12 and the SiN film 11 are etched continuously by means of a reactive ion-etching (RIE) process using SF₆. Thereby, the outer end of the polycrystalline Si gate electrode 7 and the outer end of the ON layer in the ONO gate insulating film are roughly defined. Thus, unnecessary parts of the ON layer are etched precisely (in a self-aligning manner) with the same resist mask as the polycrystalline Si gate electrode 7 is etched, in a way that the outer end of the ON layer is located at the same position as the outer end of the polycrystalline Si gate electrode 7 is located when viewed from the side. At this point, a positional relationship between the outer end of the polycrystalline Si gate electrode 7 and the outer end of the SiN film 11 depends on the RIE system and the etchant gas to be used, and remains undetermined. The outer end of the polycrystalline Si gate electrode 7 may be positioned outward of the outer end of the SiN film 11, and vice verse.

There is an important point in this respect. The point is that this continuous etching process has to be completed without causing all of the SiC thermally-oxidized film to disappear from the upper surface of the epitaxial substrate 1. If the RIE process continues being carried out until the SiC thermally-oxidized film completely disappears, plasma-induced damage is caused in the upper surface of the epitaxial substrate 1 thus exposed. For this reason, an etchant gas with a higher selective etching ratio to SiO₂ needs to be used, and an end point of the etching process needs to be detected precisely, when the SiN film 11 is intended to be etched by means of the RIE process. In this manner, careful attention needs to be paid not to perform an excessive etching process.

After the continuous etching process is completed, the resist to be used during the process is completely removed from the surface of the SiC substrate 1. Subsequently, the entire upper surface of the SiC substrate 1 is coated with a resist material (a photoresist suffices) having a thickness of 1 μm or more. While the entire upper surface of the SiC substrate 1 is being protected in this manner, the back side of the substrate 1 is etched by means of a dry etching process. Thus, the transitory polycrystalline Si film (including the polycrystalline Si thermally-oxidized film), the transitory SiN thermally-oxidized film 204 and the transitory SiN film 203, which are deposited on the back side of the SiC substrate 1, are removed sequentially. Then, the resist material to be used for protecting the upper surface of the SiC substrate 1 is removed. Thereafter, a cross-sectional structure as shown in FIG. 8C is obtained.

D. Subsequently, the SiC epitaxial substrate 1 is cleaned again by use of the RCA cleaning process, and then is dried. Thereafter, the SiC epitaxial substrate 1 is oxidized by means of a wet oxidation process (is pyrogenically oxidized) at 950° C. As shown in FIG. 8D, thereby, the polycrystalline Si thermally-oxidized film 8 is grown on the side surface and the upper portion of the polycrystalline Si gate electrode 7, and the SiN side-surface thermally-oxidized film 13 is grown on the side surface of the SiN film 11, at the same time. In this respect, there are three extremely important points for improving the reliabilities of the ONO-filmed MIS structure. A first point is that the outer end of the SiN film which has been leak-ridden as a result of being damaged during the gate etching is removed by turning the outer end into the SiN side-surface thermally-oxidized film 13. A second point is that the outer end G of the polycrystalline Si gate electrode is located slightly inward of the outer end N of the SiN film, and that accordingly the gate electric field of the outer end of the SiN film is relaxed. In the case of the manufacturing method according to the present invention, for the purpose of causing the outer end G of the polycrystalline Si gate electrode to be located slightly inward of the outer end N of the SiN film, a property that the oxidation rate of the polycrystalline Si gate electrode is higher than that of the SiN film. A third point is that addition of the polycrystalline Si thermally-oxidized film 8 and the SiN side-surface thermally-oxidized film 13 helps to establish an structure in which the ONO gate insulating film 9 locally existing under the gate electrode is completely sealed with the thermally stable materials, i.e. the polycrystalline Si film, the SiC film and the thermally-oxidized film. This structural establishment plays an important roll in preventing the ONO gate insulating film 9 from deteriorating through its interaction with surrounding materials and the environment in the course of the ensuing high-temperature contact annealing process (at 1,000° C. and for 2 minutes) or the like.

E. After the polycrystalline Si thermally-oxidized film 8 and the SiN side-surface thermally-oxidized film 13 are formed, the interlayer dielectric 14 is deposited on the entire upper surface of the epitaxial substrate 1 (as shown in FIG. 8E). A SiO₂ film with a thickness of approximately 1 μm, which is deposited by means of a normal pressure CVD process using silane and oxygen as materials, phosphorus silicate glass (PSG) with a thickness of approximately 1 μm, which is obtained by further adding phosphorus (P) to the SiO₂ film, and the like are suitable for materials for the interlayer dielectric. However, materials for the interlayer dielectric are not limited to the SiO₂ film or phosphorus silicate glass. Any other material may be used as long as the material can go through various thermal treatment processes to follow this process. Thereafter, the substrate 1 is put into a generally-used diffusion furnace, and is mildly thermally treated in a N₂ atmosphere for tens of minutes. Thus, the interlayer dielectric 14 is densified. A temperature for this thermal treatment is chosen to be lower than 1,100° C. which is used during the gate oxidation process, for example, to be in a rage of 900° C. to 1,000° C., depending on the necessity.

F. Subsequently, the upper surface of the epintaxial substrate 1 is coated with photoresist. Then, a post bake is applied thereto sufficiently, and thus volatile components of the resist are completely vaporized. Thereafter, the epitaxial substrate 1 is dipped into the buffered hydrofluoric solution, and thus the second transitory SiC thermally-oxidized film 202 which has remained on the back side of the substrate 1 is completely removed. Then, the substrate 1 is cleaned of the buffered hydrofluoric solution by use of ultrapure water. The C end surface of the back side of the SiC substrate 1 thus exposed is a clean surface free of damage or contamination. Such a surface extremely contributes to reducing resistance in the ohmic contact.

The epitaxial substrate 1, which is wet with the utrapure water, is dried. Immediately after the drying, the epitaxial substrate 1 is installed into a vapor deposition system which is kept in high vacuum. Thus, an evaporated ohmic-contact base material, which is desired, is deposited on the back side of the substrate 1. For example, a Ni film with a thickness of 50 nm to 100 nm can be used as the ohmic-contact base material.

After the evaporated ohmic-contact base material is deposited, the resist on the upper surface of the substrate 1 is completely removed with a specialized stripper solution, and the substrate 1 is cleaned fully. Thereafter, the substrate 1 is dried. Immediately after the drying, the substrate 1 is installed into a rapid thermal annealing system. Thus, a contact annealing process is applied to the substrate 1 in a 100% pure Ar atmosphere at 1,000° C. for two minutes. Through this thermal treatment process, the Ni film is alloyed with the low-resistance SiC substrate (is made into silicide), as shown in FIG. 8F. As a result, the ohmic electrode 17 with an extremely low resistance, which has a contact resistance in the order of at least 10⁻⁶ Ωcm², is obtained.

G. In the ensuing processes, the epitaxial substrate 1 is provided with the gate contact window 15 and the interconnection 16, as in the case of the first embodiment. Consequently, the ONO-filmed MIS structure according to the second embodiment of the present invention as shown in the FIG. 7 is completed.

The ONO-filmed MIS structure thus fabricated according to the second embodiment had the same reliabilities as the ONO-filmed MIS structure according to the first embodiment had (see FIGS. 4 to 6). In other words, the silicon carbide semiconductor device including the ONO-filmed MIS structure according to the present invention and the method of manufacturing the silicon carbide semiconductor device according to the present invention have an effect of completely solving the problem of having been unable to improve the reliability of the conventional ONO-filmed MIS structure to an extent that the reliability of the conventional ONO-filmed MIS structure exceeds that of the conventional SiC thermally-oxidized-film MOS structure, which problem the conventional ONO-filmed MIS structure has suffered, and an effect of achieving an extremely high durability against the dielectric breakdown and an extremely high durability against the TDDB. It is interesting to examine a case where the step D is omitted from the above-described manufacturing processes, the step D of forming the polycrystalline Si thermally-oxidized film 8 and the SiN side-suerface thermally-oxidized film 13, thereafter positioning the outer end G of the gate electrode inward of the outer end N of the SiN film when viewed from the side. An examination by the present inventor and his group confirmed that the ONO-filmed MIS structure fabricated through such a step had decreased reliabilities, and that the reliabilities were reduced to a level that made the reliabilities fall short of even the reliabilities of the conventional MOS structure with a SiC thermally oxidized film.

In addition, as clearly understood from the foregoing descriptions, in the case of the silicon carbide semiconductor device and the manufacturing method thereof according to the present invention, the ohmic contact with the extremely low resistance in the order of at least 10⁻⁶ Ωcm² is realized in the back side of the substrate 1 without decreasing the reliabilities and the yield of the ONO gate insulating film. In other words, the silicon carbide semiconductor device and the manufacturing method thereof according to the present invention have an effect of solving the problem of having still not established techniques (with regard to the structure and the manufacturing method) for forming the ohmic contact with the low resistance on the SiC substrate, which the conventional ONO-filmed MIS structure has suffered.

Furthermore, as clearly understood from the foregoing descriptions, in the case of the silicon carbide semiconductor device and the manufacturing method thereof according to the present invention, a technique is provided, which causes the unnecessary part of the SiN film in the periphery of the ONO gate insulating film to be self-aligned with the outer end of the gate electrode, and which thus removes the unnecessary part from the upper surface of the substrate 1 neither too much nor too little, without decreasing the reliabilities and the yield of the ONO gate insulating film. In other words, the silicon carbide semiconductor device and the manufacturing method thereof according to the present invention have an effect of solving the problem of leaving the unnecessary part of the ONO film outside the gate area, which the conventional techniques has been faced with. Additionally, it can be said that the manufacturing method thereof according to the present invention includes a step shorter than that of the method of removing the unnecessary part of the SiN film, which method is realized by the simple combination of the standard photolithography technique and the standard dry etching technique. It can be also said that the silicon carbide semiconductor device according to the present invention includes a structure which is suitable for reducing the size of the device.

### Third Embodiment

A third embodiment of the present invention is an example of application of the present invention to a generally-known standard n-channel planar power MOSFET cell. The present invention can be applied to a square cell, a hexagonal cell, a round cell, a linear cell and the like, no matter how shaped the cell may be.

Structure

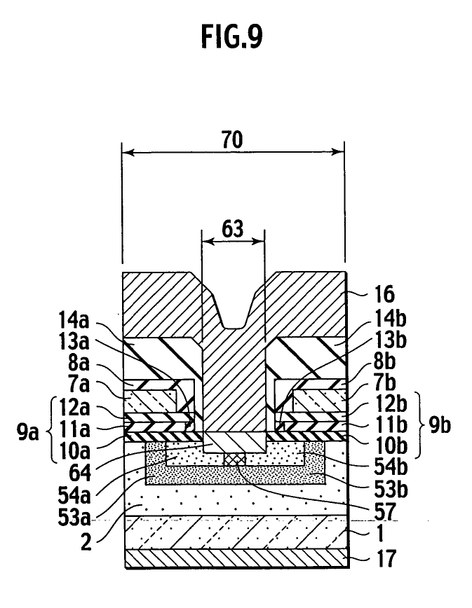

FIG. 9 is a cross-sectional view showing a chief part of the power MOSFET cell according to the third embodiment of the present invention. In FIG. 9, reference numeral 1 denotes an n⁺ single crystal SiC substrate. A first n⁻ epitaxial layer 2 with a thickness of 10 μm is grown homoepitaxially on the upper surface of the n⁺ single crystal SiC substrate 1. Nitrogen is doped to the first n⁻ epitaxial layer 2 at a concentration of 1×10¹⁶/cm³. The third embodiment can be applied to a substrate, no matter what crystal system the substrate may have, including 4H, 6H, 3C and 15R (H, C and R represent a hexagonal system, a cubic system and a rhombohedral system respectively). P-base regions 53a and 53b with a predetermined depth, to which acceptor impurities are doped in a minute amount, are formed in predetermined regions in the surface layer of the n⁻ epitaxial layer 2.

N⁺ source regions 54a and 54b are formed in predetermined regions in the surface layer of the p-base regions 53a and 53b in a way that the n⁺ source region 54a extends from the outer boundary of the p-base regions 53a for the same distance as the n⁺ source region 54b extends from the outer boundary of the p-base regions 53b. The n⁺ source regions 54a and 54b have smaller depths than the p-base regions 53a and 53b respectively. A p⁺ base contact region 57 are arranged in the surface layer of the substrate in the middle between the p-base regions 53a and 53b in a way that the p⁺ base contact region 57 has a smaller depth than that of each of the p-base regions 53a and 53b, and in a way that the p⁺ base contact region 57 is interposed between the n⁺ source regions 54a and 54b.

Reference numerals 9a and 9b denote ONO gate insulating films which are formed selectively on the upper surface of the substrate 1. Each of the ONO insulating films 9a and 9b is three-layered. From bottom (nearer to the substrate 1) to top, a SiC thermally-oxidized film 10a, a SiN film 11a and a SiN thermally-oxidized film 12a are laid over one another, and a SiC thermally-oxidized film 10b, a SiN film 11b and a SiN thermally-oxidized film 12b are laid over one another. A SiN side-surface thermally-oxidized film 13a to be formed by thermally oxidizing an end portion of the SiN film 11a is arranged on the side wall of the SiN film 11a, and a SiN side-surface thermally-oxidized film 13b to be formed by thermally oxidizing an end portion of the SiN film 11b is arranged on the side wall of the SiN film 11b.

A gate electrode 7a made of polycrystalline Si, to which conductivity is given, is provided onto the ONO gate insulating film 9a in a way that the outer end of the gate electrode 7a is located at the same position as the outer end of the SiN thermally-oxidized film 12a is located. A gate electrode 7b made of polycrystalline Si, to which conductivity is given, is provided onto the ONO gate insulating film 9b in a way that the outer end of the gate electrode 7b is located at the same position as the outer end of the SiN thermally-oxidized film 12b is located. A polycrystalline Si side-surface thermally-oxidized film 8a is formed on the upper portion and the side wall of the polycrystalline Si gate electrode 7a, and a polycrystalline Si side-surface thermally-oxidized film 8b is formed on the upper portion and the side wall of the polycrystalline Si gate electrode 7b.

An interlayer dielectric 14a is formed above the SiC substrate 1, including the polycrystalline Si side-surface thermally-oxidized film 8a. An interlayer dielectric 14b is formed above the SiC substrate 1, including the polycrystalline Si side-surface thermally-oxidized film 8b. Reference numeral 63 denotes a source window which is opened in the interlayer dielectric 14a and 14b. The source window 63 is opened in a way that the source window 63 reaches the n⁺ source regions 54a and 54b as well as the p⁺ base contact region 57. A source electrode 64 exists in the bottom of the source window 63. The source electrode 64 is formed by selectively arranging a base material in the form of a thin metal film in the bottom of the source window 63, and by thereafter alloying the base material with SiC by means of a rapid thermal annealing. The source electrode 64 forms its ohmic contact with the n⁺ source regions 54a and 54b as well as the p⁺ base contact region 57 at the same time. What on the back side of the substrate 1 is denoted by reference numeral 17 is a drain electrode to be formed by means of the same method as the source electrode 64 is formed. Reference numeral 16 denotes an interconnection for connecting the source electrode 64 with other circuit elements in the same substrate as the source electrode is located, and with external circuits through the source window 63.

Manufacturing Method

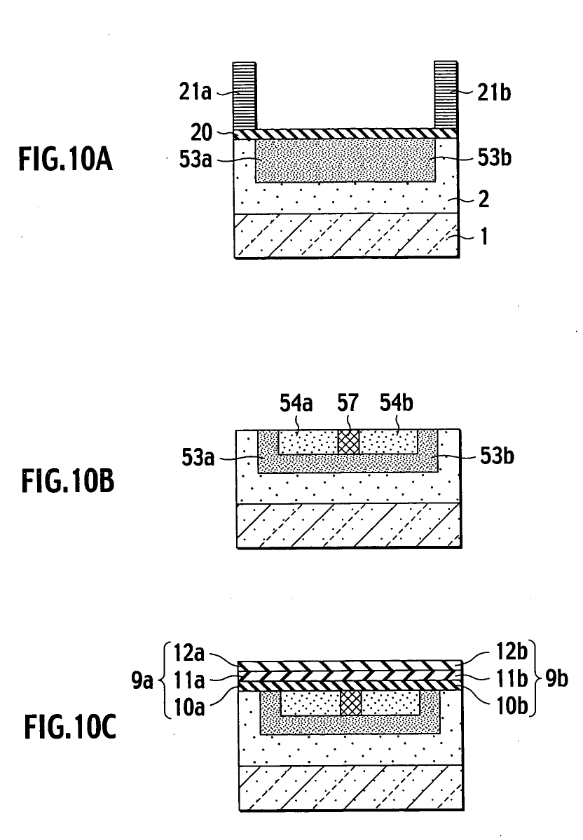

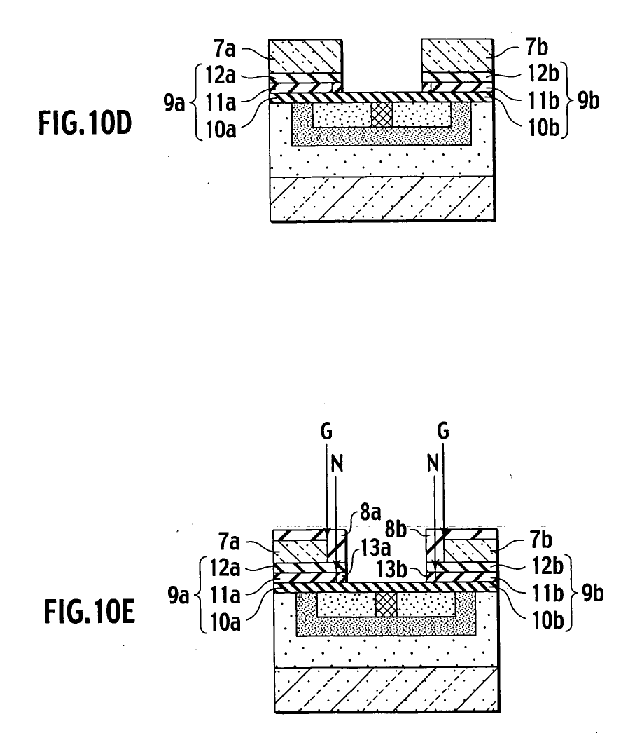

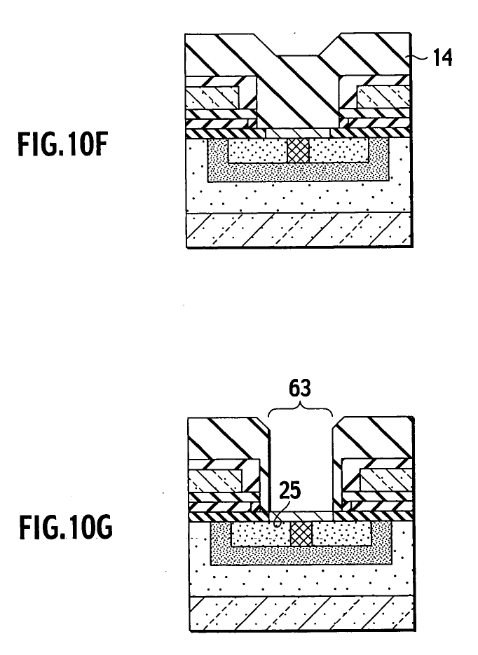

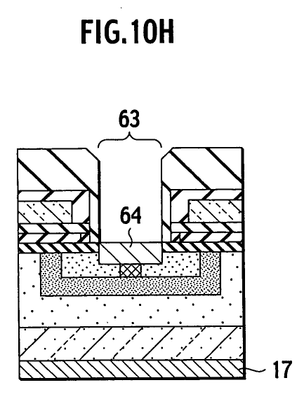

Next, descriptions will be provided for a method of manufacturing the planar power MOSFETs according to the third embodiment of the present invention with reference to FIGS. 10A to 10G.

A. The n⁺ SiC substrate 1 is prepared by homoepitaxially growing the n⁻ epitaxial layer 2 on the principal surface of the substrate 1. Subsequently, a CVD oxide film 20 with a thickness of 20 nm to 30 nm is deposited on the surface of the n⁻ epitaxial layer 2. Thereafter, a film of approximately 1.5 μm in thickness as a mask material to be used for an ion implantation process is formed on the CVD oxide film 20 by depositing polycrystalline Si by means of a low pressure chemical vapor deposition (LPCVD) method. SiO₂, PSG (phosphorus silicate glass) or the like, each of which is formed by a CVD process, can be used instead of polycrystalline Si. The CVD oxide film 20 can be omitted. When polycrystalline Si is intended to be used as a mask material for an ion implantation process, it is recommendable that the CVD oxide film 20 be formed. That is because the CVD oxide film 20 has useful effects and functions as follows. The effects and function are (a) serving as a protection film for preventing the polycrystalline Si and the n⁻ epitaxial layer 2 from interacting with each other in an unexpected manner; (2) detecting an end point in a case where the polycrystalline Si mask material is etched anisotropically, and serving as an etching stopper film; and (3) serving as a film for protecting a surface when p-base dopants are implanted.

Subsequently, the polycrystalline Si film on a region where a p-base region is planned to be formed is removed vertically by use of a photolithography process and by use of an anisotropic etching process such as a reactive ion etching (RIE) process. Thereby, first ion-implantation masks 21a and 21b are formed. If an etchant gas such as SF₆ is used when the polycrystalline Si film is etched by means of the RIE process, this enables the thermal oxide film to be etched with a high selective etching ratio, and this enables an end point of etching to be detected. Accordingly, this makes it possible to avoid plasma-induced damage that would otherwise occur on the upper surface of the substrate 1, especially on the channel region.

Thereafter, p-type impurities are implanted into the n⁻ epitaxial layer 2, and thereby the p-base regions 53a and 53b are formed, as shown in FIG. 10A. Although the polycrystalline Si is actually deposited to the back side of the epitaxial substrate 1, the polycrystalline Si thus deposited is not illustrated in FIG. 10A. Examples of conditions under which ions are selectively implanted into the p-base regions 53a and 53b are as follows:
Dopants: Al⁺ ions
Substrate temperature: 750° C.
Acceleration voltage/dose: 360 keV/5×10⁻¹³ cm⁻²

After ions are implanted into the p-base regions 53a and 53b, the CVD oxide film 20 as well as the first ion-implantation masks 21a and 21b are removed by means of a wet etching process.

B. Subsequently, as shown in FIG. 10B, the n⁺ source regions 54a and 54b as well as the p⁺ base contact region 57 are formed by use of the same procedure as ions have been selectively implanted into the p-base regions 53a and 53b. Examples of conditions under which ions are selectively implanted into the n⁺ source regions 54a and 54b are as follows:
Dopants: P⁺ ions
Substrate temperature: 500° C.
Acceleration voltage/dose: 160 keV/2.0×10¹⁵ cm⁻²
   100 keV/1.0×10¹⁵ cm⁻²
   70 keV/6.0×10¹⁴ cm⁻²
   40 keV/5.0×10¹⁴ cm⁻²

In addition, examples of conditions under which ions are selectively implanted into the p+base contact region 57 are as follows:
Dopants: Al⁺ ions
Substrate temperature: 750° C.
Acceleration voltage/dose: 100 keV/3.0×10¹⁵ cm⁻²
   70 keV/2.0×10¹⁵ cm⁻²
50 keV/1.0×10¹⁵ cm⁻²
30 keV/1.0×10¹⁵ cm⁻²

After all of the ion implantation processes are completed, the substrate 1 is dipped into a mixed solution of hydrofluoric acid and nitric acid. Thereby, all of the masks to be used and all of the unnecessary mask materials to be deposited to the back side of the substrate 1 are completely removed. When the masks are intended to be removed, a method may be used, in which the substrate is dipped into a thermal phosphoric acid solution and a BHF solution alternately, and in which thereby the polycrystalline Si and the SiO₂ are removed sequentially.

Subsequently, the substrate 1 from which the masks have been removed is cleaned, and is dried. Thereafter, the substrate 1 is thermally treated in an atmospheric pressure pure Ar atmosphere at 1,700° C. for one minute. Thereby, all of the conductive dopants which have been implanted into the p-base regions 53a and 53b, the n⁺ source regions 54a and 54b, and the p⁺ base contact region 57 are activated at once.

C. The substrate 1 which has been fully cleaned by use of an RCA cleaning process or the like is thermally oxidized in a dry oxygen atmosphere. Thereby, thermal oxide films are grown on the upper surface and the back side of the substrate 1. Immediately after the growth is completed, the thermal oxide films are removed by use of a buffered hydrofluoric solution. It is advantageous that the thickness of each of these sacrificial oxide films be less than 50 nm. It is preferable that the thickness be 5 nm to 20 nm. The substrate 1, on which the sacrificial oxidation process has been completed, is cleaned fully again by an RCA cleaning process or the like. Thereafter, a thick insulating film is formed on the surface of the substrate 1 by use of a thermal oxidation process, a CVD process or the like. Subsequently, an active region (unit cell) 70 (see FIG. 9), from which a field region (not illustrated) where the thick oxide film exists and the thick oxide film are removed, is formed by use of a generally-known photolithography process and by use of a wet etching process or a dry etching process. Incidentally, a shape which the active region 70 has assumed at this stage is as shown in FIG. 10B. However, the shape of the active region 70 is different from the shape represented by FIG. 10B in that the field region is formed in the outer periphery of the active region 70.

Then, the substrate 1 is fully cleaned again by use of an RCA cleaning process or the like. At a final stage of this cleaning process, the substrate 1 is dipped in a diluted hydrofluoric solution for 5 to 10 seconds for the purpose of removing a chemical oxide film (SiO₂) which has been formed on the surface of the element region 70. Subsequently, the substrate 1 is cleaned of the diluted hydrofluoric acid solution completely by use of ultrapure water. Thereafter, the substrate 1 is dried. Immediately after the drying, the substrate 1 is thermally oxidized. Thereby, SiC thermally-oxidized films 10a and 10b, which respectively constitute first layers of the ONO gate insulating films 9a and 9b, are formed above the surface of the substrate 1 in the element region 70. Thereafter, SiN films 11a and 11b as second layers of the ONO gate insulating films 9a and 9b are deposited on the SiC thermally-oxidized films 10a and 10b by use of a LPCVD process. Finally, the SiN films 11a and 11b are thermally oxidized. Thereby, SiN thermally-oxidized films 12a and 12b as third layers of the ONO gate insulating films 9a and 9b are grown on the surfaces respectively of the SiN films 11a and 11b. Consequently, a structure as shown in FIG. 10C is obtained. Although an ONO-structured film is also formed on the back side of the epitaxial substrate 1, the ONO-structured film is not illustrated in FIG. 10C. Each of the films in the case of the third embodiment of the present invention can be formed by use of the same conditions as each of the films in the case of the first and the second embodiments of the present invention is formed.

In this respect, it is an important point that the thermal oxidation temperature for the SiC thermally-oxidized films 10a and 10b be set to be higher than a temperature for any one of the ensuing processes. In the case of this embodiment, a rapid heating process is performed at a temperature of 1,000° C. later for the purpose of achieving an ohmic contact between the source contact electrode 64 above the upper surface of the substrate 1 and the drain electrode 17 on the back side of the substrate 1. For this reason, 1,100° C., which is higher than that temperature, is chosen to be an oxidation temperature.

D. Thereafter, a polycrystalline Si film with a thickness of 300 nm to 400 nm is formed on the entire upper surface and the entire back side of the substrate 1 by means of a low pressure CVD process using a silane material (at a growth temperature of 600° C. to 700° C.). Thereafter, phosphorus (P) is doped to the polycrystalline Si film by means of a generally-known thermal diffusion method using phosphorus chlorate (POCl₃) and oxygen (at a processing temperature of 900° C. to 950° C.). Thereby, conductivity is given. Then, the upper surface of the substrate 1 is coated with photoresist. Subsequently, the polycrystalline Si film above the upper surface of the substrate 1, unnecessary parts of the SiN thermally-oxidized films 12a and 12b of the ONO gate insulating film 9a and 9b, as well as unnecessary parts of the SiN films 11a and 11b of the ONO gate insulating film 9a and 9b are removed continuously by use of a photolithography process and by use of a reactive ion etching (RIE) process using C₂F₆ and oxygen as etchants. Then, the resist is removed. Consequently, a structure as shown in FIG. 10D is obtained. In this step, the gate electrodes 7a and 7b are defined. Incidentally, the polycrystalline Si film is also formed on the back side of the epitaxial substrate 1. However, this polycrystalline Si film is not illustrated in FIG. 10D.

E. Subsequently, the SiC epitaxial substrate 1, which has been etched by use of the RIE process, is cleaned by means of an RCA cleaning process, and then is dried. Thereafter, the SiC epitaxial substrate 1 is oxidized by means of a wet oxidation process (is pyrogenically oxidized) at 950° C. As shown in FIG. 10E, thereby, the polycrystalline Si thermally-oxidized films 8a is grown on the side surface and the upper portion of the polycrystalline Si gate electrode 7a, and the SiN side-surface thermally-oxidized film 13a is grown on the side surface of the SiN film 11a, at the same time. Simultaneously with this, the polycrystalline Si thermally-oxidized films 8b is grown on the side surface and the upper portion of the polycrystalline Si gate electrode 7b, and the SiN side surface thermally-oxidized film 13b is grown on the side surface of the SiN film 1b, at the same time. Through these processes, the reliabilities of the ONO-filmed MIS structure are intended to be improved as follows. The side surface of the outer end of the SiN film which has been electrically leaky as a result of being damaged during the gate etching is removed by turning the side surface into the SiN side-surface thermally-oxidized films 13a and 13b. Furthermore, the outer end G of the polycrystalline Si gate electrode is positioned slightly inward of the outer end N of the SiN film when viewed from the side. Accordingly, the gate electric field of the outer end of the SiN film is relaxed. In the case of the manufacturing method according to the present invention, for the purpose of causing the outer end G of the polycrystalline Si gate electrode to be located slightly inward of the outer end N of the SiN film, a property that the oxidation rate of the polycrystalline Si is higher than that of the SiN film. Moreover, through these processes, addition of the polycrystalline Si thermally-oxidized films 8a and 8b as well as the SiN side-surface thermally-oxidized film 13a and 13b helps to establish an structure in which the ONO gate insulating film 9a and 9b locally existing under the gate electrode 7a and 7b are completely sealed with the thermally stable materials, i.e. the polycrystalline Si film, the SiC film and the thermal oxide film. This structural establishment plays an important role in preventing the ONO gate insulating film 9a and 9b from deteriorating through their interaction with surrounding materials and the environment in the course of the ensuing high-temperature contact annealing process (at 1,000° C. for 2 minutes) or the like. Incidentally, the polycrystalline Si thermally-oxidized film 8a is formed not only on the side wall of the gate electrode 7a, but also on the upper surface of the gate electrode 7a. In addition, the polycrystalline Si thermally-oxidized film 8b is formed not only on the side wall of the gate electrode 7b, but also on the upper surface of the gate electrode 7b. This makes the polycrystalline Si gate electrodes 7a and 7b come short of their full thicknesses. For this reason, suppose that, with this shortage taken into consideration, the initial thicknesses of the polycrystalline Si gate electrodes 7a and 7b have been defined.

F. Subsequently, an interlayer dielectric 14 is deposited on the entire upper surface of the substrate 1, as shown in FIG. 10F. A SiO₂ film (NSG) with a thickness of approximately 1 μm, which is formed by means of a normal pressure CVD process using silane and oxygen as materials, phosphorus silicate glass (PSG) with a thickness of approximately 1 μm, which is obtained by further adding phosphorus (P) to the SiO₂ film, and boron phosphorus silicate glass (BPSG) with a thickness of approximately 1 μm, which is obtained by further adding boron thereto, are suitable for materials for the interlayer dielectric 14. However, materials for the interlayer dielectric are not limited to the SiO₂ film, phosphorus silicate glass, or boron phosphorus silicate glass. Thereafter, the substrate 1 is put into a generally-used diffusion furnace, and is mildly thermally treated in a N₂ atmosphere for tens of minutes. Thus, the interlayer dielectric 14 is densified. A temperature for this thermal treatment is chosen to be lower than a temperature at which the gate insulating film is formed (thermally oxidized), for example, to be in a range of 900° C. to 1,000° C., depending on the necessity.

G. Thereafter, the source window 63 is opened in the interlayer dielectric 14 above the upper surface of the substrate 1 as well as the SiC thermally-oxidized films 10a and 10b in the ONO gate insulating film by use of a generally-known photolithography process and by use of a dry/wet etching process. Although not illustrated, the gate contact window to be formed in the periphery of the element region is also opened at the same time. In a case where an etchant solution or an etchant gas reaches the back side of the substrate 1, a thermal oxide film (not illustrated) on the transitory polycrystalline Si film on the back side.

After the etching, an evaporated base material 25 for the source contact electrode is deposited above the entire upper surface of the substrate 1, above which the photoresists and the etching masks have remained, by use of a film formation process including a DC sputtering process. For example, a Ni film, a Co film and the like, with a thickness of 50 nm, can be used as the base material 25 for the source-contact electrode.

After the vapor deposition process is completed, the substrate 1 is dipped in a specialized photoresist stripper, and thereby the photoresist which has remained above the substrate 1 is completed removed. Thus, a substrate structure is obtained, in which the base material 25 for the source contact electrode is deposited only on the source window 63 and in the bottom of the gate contact window (lead lines are illustrated, and its corresponding reference numeral is omitted), as shown in FIG. 10G.

H. Then, the substrate is fully cleaned, and is dried. Thereafter, the entire upper surface of the substrate is coated with a protective resist material (photoresist suffices) with a thickness of 1 μm or more. Then, the substrate is etched by means of a dry etching process. Thereby, the polycrystalline silicon film, the SiN thermally-oxidized film and the SiN film, which remain on the back side of the substrate, are removed sequentially. The aforementioned protective resist material is needed to prevent the base material 25 for the contact electrode as well as the gate insulating films 10a and 10b from being deteriorated due to plasma-induced damage, electrostatic charge and contamination which are caused during a dry etching process.

Afterward, the substrate 1 is dipped into a buffered hydrofluoric solution. Thereby, a transitory SiC thermally-oxidized film (not illustrated), which is formed while the SiC thermally oxidized films of the ONO film is being grown, is removed. Thus, a clean crystal plane is exposed in the back side of the epitaxial substrate 1. Then, the substrate is cleaned of the buffered hydrofluoric solution completely by use of ultrapure water, and is dried. Immediately after the drying, the substrate 1 is installed in a vapor deposition system which is kept in high vacuum. Thus, an evaporated base material (not illustrated) for a drain contact electrode, which is desired, is deposited on the back side of the substrate. For example, a Ni film or a Co film, with a thickness of 50 nm to 100 nm, can be used as the base material for the electrode on the back side.

Next, the resist which has been used to protect the surface of the substrate is completely removed by use of a specialized stripper solution. Then the epitaxial substrate 1 is fully cleaned, rinsed, and dried. Immediate after the drying, the substrate 1 is installed in a rapid heating process system. Thus, the rapid heating process (contact annealing process) is applied to the substrate 1 in a pure Ar atmosphere at 1,000° C. for 2 minutes. Through this thermal treatment, each of the bases materials (Ni film) for contact electrodes which has been deposited in the bottoms respectively of the source window 63 and the gate contact window is alloyed with the n⁺ source region 54a, the n⁺ source region 54b, the p⁺ base contact region 57, or the polycrystalline Si gate electrode contact region (not illustrated). In addition, each of the bases materials for contact electrodes which has been deposited on the back side of the substrate 1 is alloyed with the back side of the n⁺ SiC substrate 1. Accordingly, a source electrode 64 which is ohmically contacted with an extremely low resistance, a gate contact (not illustrated) and a drain contact electrode 17 are formed. Consequently, a substrate structure as shown in FIG. 10H is obtained.

I. Thereafter, the substrate 1, to which the contact annealing process has been applied, is installed into a magnetron sputtering system which is kept in high vacuum. Thereby, an evaporated material for interconnection, which is desired, is deposited above the substrate 1, and, for example, an Al film of 3 μm in thickness is formed above the substrate 1.

Subsequently, photoresist is applied above the upper surface of the substrate 1, above which the Al film has been formed. The photoresist is exposed, and developed. Thus, a resist mask for an etching process is formed. Thereafter, the back side of the substrate 1 is coated with photoresist for protecting a back-side electrode. After the resist is fully dried, the Al film is patterned by use of an RIE process. Accordingly, the interconnection 16 to be connected to the source contact electrode 64 and an interconnection (not illustrated) to be connected to the gate contact are formed.

Finally, the resist mask is removed completely by use of a specialized stripper solution. The substrate 1 is fully rinsed, and dried. Thus, the planar power MOSFET cell according to the present invention, as shown in FIG. 9, is completed.

The planar power MOSFET cell including the ONO-filmed MIS structure according to the present invention, which was fabricated in the aforementioned manner, demonstrated the same preferable transistor characteristics as a planar power MOSFET cell including a standard SiC thermally-oxidized gate oxide film demonstrated.

Components of the ONO-filmed MIS structure demonstrated the same high reliabilities as components of the ONO-filmed MIS structure according to the first embodiment demonstrated (see FIGS. 4 to 6). In other words, the planar power MOSFET cell with the ONO-filmed MIS structure and the manufacturing method thereof according to the present invention has an effect of remarkably improving reliabilities, for example, durability against the dielectric breakdown and durability against the TDDB, of the gate insulating film in a SiC thermally-oxidized-filmed MOS gate structure included in a conventional planar power MOSFET. Accordingly, the planar power MOSFET cell and the manufacturing method thereof according to the present invention have an effect of remarkably prolonging the life span.

Furthermore, as clearly understood from the foregoing descriptions, in the case of the planar power MOSFET cell and the manufacturing method thereof according to the present invention, the ohmic contact with the extremely low resistance in the order of at least 10⁻⁶ Ωcm² can be realized in the back side of the substrate 1 without decreasing the reliabilities and the yield of the ONO gate insulating film. In other words, the planar power MOSFET cell and the manufacturing method thereof according to the present invention have an effect of solving the problem of having still not established techniques for forming the source contact or the drain contact with a low resistance, which problem the conventional planar power MOSFET cell with an ONO-filmed MIS structure and the conventional manufacturing method thereof have potentially suffered. Additionally, it can be said that, since contact resistances respectively of the source contact and the drain contact are decreased, the planar power MOSFET cell and the manufacturing method thereof according to the present invention have an effect of being able to reduce an on-resistance of the planar power MOSFETs.

Furthermore, as clearly understood from the foregoing descriptions, in the case of the planar power MOSFET cell with an ONO gate structure and the manufacturing method thereof according to the present invention, a technique is provided, which causes the unnecessary parts of the SiN films in the periphery of the ONO gate structure to be self-aligned with the outer ends of the gate electrodes 7a and 7b, and which thus removes the unnecessary parts from the upper surface of the substrate 1 neither too much nor too little, without decreasing the reliabilities and the yield of the ONO gate insulating films. In other words, the planar power MOSFET cell with an ONO gate structure and the manufacturing method thereof according to the present invention have an effect of solving the problem of leaving the unnecessary parts of the ONO film outside the gate area, and the problem of accordingly hindering the miniaturization and the improvement in the yield, which problems the conventional planar power MOSFET cell with an ONO gate structure and the conventional manufacturing method thereof have been faced with.

### Fourth Embodiment

The third embodiment is application of the ONO-filmed gate structure according to the present invention to the planar power MOSFET cell. However, it goes without saying that the present invention can be applied to an insulated gate bipolar transistor (IGBT) cell which includes an element structure similar to that of the planar power MOSFET cell. In this case, the insulated gate bipolar transistor (IGBT) cell has the same effects as the planar power MOSFET cell according to the third embodiment.

The entire content of a Patent Application No. TOKUGAN 2004-227704 with a filing date of Aug. 4, 2004 in Japan is hereby incorporated by reference.

Although the invention has been described above by reference to certain embodiments of the invention, the invention is not limited to the embodiments described above. Modifications and variations of the embodiments described above will occur to those skilled in the art, in light of the teachings. The scope of the invention is defined with reference to the following claims.

What is claimed is:

1. A silicon carbide semiconductor device comprising:
a silicon carbide substrate;
a gate electrode made of polycrystalline silicon;
a three-layered gate insulating film made of a silicon oxide film, a silicon nitride film and a silicon nitride thermally-oxidized film, interposed between the silicon carbide substrate and the gate electrode;
a polycrystalline silicon thermally-oxidized film provided onto at least a side wall of the gate electrode; and
a silicon nitride side-surface thermally-oxidized film provided onto at least a side wall of the silicon nitride film.

2. The silicon carbide semiconductor device according to claim 1,
wherein an outer end of the polycrystalline silicon thermally-oxidized film is located at the same position as an outer end of the silicon nitride side-surface thermally-oxidized film is located, and
wherein an outer end of the silicon nitride film is positioned outward of an outer end of the gate electrode.

3. A silicon carbide semiconductor device comprising:
a silicon carbide substrate,
a gate electrode made of polycrystalline silicon;
a three-layered gate insulating film made of a silicon oxide film, a silicon nitride film and a silicon nitride thermally-oxidized film, interposed between the silicon carbide substrate and the gate electrode;
a polycrystalline silicon thermally-oxidized film provided onto a side wall of the gate electrode; and
a silicon nitride side-surface thermally-oxidized film provided onto a side wall of the silicon nitride film,
wherein the silicon nitride thermally-oxidized film and the gate electrode are provided thereto in a way that an outer end of the silicon nitride film is positioned outward of an outer end of the gate electrode.

4. The silicon carbide semiconductor device according to claim 3, further comprising:
an interlayer dielectric placed on an upper surface of the silicon carbide semiconductor device in a way that the interlayer dielectric covers at least a part of an upper portion of the gate electrode; and
an electrode ohmically connected to the silicon carbide substrate, placed on a predetermined region on any one of a back side and the upper surface of the silicon carbide semiconductor device.

5. A silicon carbide semiconductor device comprising:
a silicon carbide substrate on whose upper surface a field insulating film through which a gate window is opened is formed;
a gate electrode made of polycrystalline silicon;
a three-layered gate insulating film made of a silicon oxide film, a silicon nitride film and a silicon nitride thermally-oxidized film, interposed between the silicon carbide substrate and the gate electrode in a way that the three-layered gate insulating film covers the gate window;
a polycrystalline silicon thermally-oxidized film provided onto a side wall of the gate electrode; and
a silicon nitride side-surface thermally-oxidized film provided onto a side wall of the silicon nitride film,
wherein the silicon nitride film and the gate electrode are provided thereto in a way that an outer end of the silicon nitride film is positioned outward of an outer end of the gate electrode.

6. The silicon carbide semiconductor device according to claim 1, wherein the silicon carbide semiconductor device is a MOSFET.

7. The silicon carbide semiconductor device according to claim 1, wherein the silicon carbide semiconductor device is an IGBT.

8. A method of manufacturing the silicon carbide semiconductor device according to claim 1, wherein the silicon oxide film is formed by thermally oxidizing the silicon carbide substrate.

9. A method of manufacturing the silicon carbide semiconductor device according to claim 1, wherein the silicon oxide film is formed by depositing a silicon oxide film by use of a chemical vapor deposition method, and thereafter by thermally treating the silicon oxide film thus deposited any one of in an oxidized atmosphere and in an inactive atmosphere.

10. A method of manufacturing the silicon carbide semiconductor device according to claim 1, comprising an act of forming the polycrystalline silicon thermally-oxidized film and the silicon nitride side-surface thermally-oxidized film by a thermal oxidation process at the same time.

11. A method of manufacturing the silicon carbide semiconductor device according to claim 2, comprising the acts of:
continuously etching the gate electrode and the silicon nitride film by use of the same mask, and thereby preliminarily defining the outer ends respectively of the gate electrode and the silicon nitride film; and
thereafter thermally oxidizing the gate electrode and the silicon nitride film at the same time, and finally determining the outer ends respectively of the gate electrode and the silicon nitride film.

12. A method of manufacturing the silicon carbide semiconductor device according to claim 11, wherein the act of continuously etching the gate electrode and the silicon nitride film by use of the same mask is an act in which the continuous etching process is stopped without that the continuous etching process does not penetrate the silicon oxide film.

13. A method of manufacturing the silicon carbide semiconductor device according to claim 3, comprising the acts of:
laying a silicon oxide film, a silicon nitride film and a silicon nitride thermally-oxidized film over one another sequentially on a silicon carbide substrate, and thereby forming a three-layered gate insulating film;
laying a gate electrode made of polycrystalline silicon on the silicon nitride thermally-oxidized film;
continuously removing an unnecessary part of the gate electrode and an unnecessary part of the silicon nitride film from the silicon carbide substrate by use of the same mask, and thus preliminarily defining outer ends respectively of the gate electrode and the silicon nitride film; and
thermally oxidizing the gate electrode and the silicon nitride film, thus forming a polycrystalline silicon thermally-oxidized film on the two sides of the gate electrode and forming a silicon nitride side-surface thermally oxidized film on the two sides of the silicon nitride film, and thereafter positioning an outer end of the gate electrode inward of an outer of the silicon nitride film.

14. A method of manufacturing the silicon carbide semiconductor device according to claim 5, comprising the acts of:
forming a field insulating film, through which a gate window is opened, on a silicon carbide substrate;
forming a three-layered gate insulating film by sequentially laying a silicon oxide film, a silicon nitride film and a silicon nitride thermally-oxidized film over one another in a way that the silicon oxide film, the silicon nitride film and the silicon nitride thermally-oxidized film cover a bottom of the gate window;
forming a gate electrode made of polycrystalline silicon on the silicon nitride thermally-oxidized film;
continuously removing an unnecessary part of the gate electrode and an unnecessary part of the silicon nitride film from the silicon carbide substrate by use of the same mask, and thus preliminarily defining outer ends respectively of the gate electrode and the silicon nitride film; and
thermally oxidizing the gate electrode and the silicon nitride film, thus forming a polycrystalline silicon thermally-oxidized film on the two sides of the gate electrode and forming a silicon nitride side-surface thermally oxidized film on the two sides of the silicon nitride film, and thereafter positioning an outer end of the gate electrode inward of an outer of the silicon nitride film.

15. A method of manufacturing the silicon carbide semiconductor device according to claim 5, comprising the acts of:
laying a silicon oxide film, a silicon nitride film and a silicon nitride thermally-oxidized film over one another sequentially on a silicon carbide substrate, and thereby forming a three-layered gate insulating film;
forming a gate electrode made of polycrystalline silicon on the silicon nitride thermally-oxidized film;
continuously removing an unnecessary part of the gate electrode and an unnecessary part of the silicon nitride film from the silicon carbide substrate by use of the same mask, and thus preliminarily defining outer ends respectively of the gate electrode and the silicon nitride film;
thermally oxidizing the gate electrode and the silicon nitride film, thus forming a polycrystalline silicon thermally-oxidized film on the two sides of the gate electrode and forming a silicon nitride side-surface thermally oxidized film on the two sides of the silicon nitride film, and thereafter positioning an outer end of the gate electrode inward of an outer of the silicon nitride film;
depositing an interlayer dielectric in a way that the interlayer dielectric covers the polycrystalline silicon thermally-oxidized film;
exposing a predetermined region in the silicon carbide substrate;
providing an ohmic contact base material at least in the exposed region in the silicon carbide substrate; and
thermally oxidizing the silicon carbide substrate, and thereby making the ohmic contact base material into an ohmically-contacted electrode with a low resistance.
